(19) United States
(12) Patent Application Publication
(10) Pub. No.: US 2025/0014897 A1
(43) Pub. Date: Jan. 9, 2025

(54) SEMICONDUCTOR SUBSTRATE, MANUFACTURING METHOD THEREOF AND MANUFACTURING APPARATUS

(71) Applicant: ROHM CO., LTD., Kyoto (JP)

(72) Inventors: Makoto TAKAMURA, Kyoto (JP); Takayasu OKA, Kyoto (JP)

(73) Assignee: ROHM CO., LTD., Kyoto (JP)

(21) Appl. No.: 18/758,611

(22) Filed: Jun. 28, 2024

(30) Foreign Application Priority Data
Jul. 5, 2023 (JP) 2023-111051

(51) Int. Cl. H01L 21/02; C30B 25/10; C30B 25/18; H01L 21/265; H01L 29/16

(52) U.S. Cl. CPC H01L 21/02529; C30B 25/10; C30B 25/18; H01L 21/02378; H01L 21/02444; H01L 21/02447; H01L 21/2652; H01L 29/1608

(57) ABSTRACT

The present disclosure provides a method of manufacturing a semiconductor substrate. The method includes: forming a graphene layer on a silicon plane of a silicon carbide monocrystalline substrate; forming a SiC epitaxial growth layer on the graphene layer; forming a stress layer on the SiC epitaxial growth layer; attaching a temporary substrate onto the stress layer; peeling off the graphene layer from the SiC epitaxial growth layer; forming a SiC polycrystalline growth layer on a carbon plane of the SiC epitaxial growth layer from which the graphene layer has been peeled off; and removing the temporary substrate. At least one of the forming of the graphene layer and the forming of the SiC epitaxial growth layer is under an atmosphere including fluorine.

### TECHNICAL FIELD

The present disclosure relates to a semiconductor substrate, a manufacturing method thereof and a manufacturing apparatus.

### BACKGROUND

In recent years, compared with Si semiconductors and GaAs semiconductors, silicon carbide (SiC) semiconductors that can achieve wider bandgap energy, high electric field withstand voltage performance, high withstand voltage, high current, low on-resistance, high efficiency, low power consumption, and high-speed switching are attracting attention. The development of SiC power devices used for power control, such as Schottky barrier diode (SBD), metal oxide semiconductor field effect transistor (MOSFET), insulated gate bipolar transistor (IGBT), etc., is advancing. The SiC semiconductor substrate forming such a SiC power device is sometimes produced by bonding a monocrystalline SiC semiconductor substrate to a polycrystalline SiC semiconductor substrate by room temperature bonding or diffusion bonding in order to reduce manufacturing costs or provide required physical properties. (For example, referring to Patent Document 1).

### BACKGROUND TECHNICAL DOCUMENTS

### Patent Documents

[Patent Document 1] U.S. Pat. No. 8,916,451

### BRIEF DESCRIPTION OF THE DRAWINGS

FIG. 1 shows a cross-sectional view of a SiC monocrystalline substrate.

FIG. 2A is a top view illustrating a crystal plane of a SiC wafer.

FIG. 2B shows a side view illustrating a crystal plane of a SiC wafer.

FIG. 3A shows a perspective view of a unit group of a 4H—SiC crystal.

FIG. 3B shows a structural diagram of a two-layer portion of the 4H—SiC crystal.

FIG. 3C shows a structural diagram of a four-layer portion of the 4H—SiC crystal.

FIG. 4 shows a structural diagram of the unit group of the 4H—SiC crystal shown in FIG. 3A when viewed from directly above the (0001) plane.

FIG. 5 shows a cross-sectional view of a first composite in which a graphene layer is formed on a SiC monocrystalline substrate.

FIG. 6 is a perspective view showing an example of a graphene layer having a structure in which multiple layers are laminated.

FIG. 7 is a flowchart showing a series of steps for forming a graphene layer.

FIG. 8 is a cross-sectional view showing a semiconductor manufacturing apparatus.

FIG. 9 is a flowchart showing a series of steps for forming a graphene layer according to a modified example.

FIG. 10 shows a cross-sectional view of a second composite in which a SiC epitaxial growth layer is formed on the graphene layer.

FIG. 11 is a flowchart showing a series of steps for forming a SiC epitaxial growth layer.

FIG. 12 is a cross-sectional view showing a semiconductor manufacturing apparatus according to a modified example.

FIG. 13 is a cross-sectional view of a third composite in which a stress layer is formed on the second composite.

FIG. 14 is a cross-sectional view of a fourth composite in which the stress layer of the third composite is attached to a graphite substrate via an adhesive layer.

FIG. 15 shows a cross-sectional view of a fifth composite in which each of both surfaces of the graphite substrate is attached with the stress layer of the second composite via an adhesive layer.

FIG. 16 shows a cross-sectional view of the fifth composite broken at the interface between the graphene layer and the SiC epitaxial growth layer.

FIG. 17 shows a sixth composite in which the SiC epitaxial growth layers are laminated on both sides of the graphite substrate via the adhesive layers respectively.

FIG. 18 shows a cross-sectional view of a seventh composite in which a SiC polycrystalline growth layer is formed on the sixth composite by a chemical vapor deposition (CVD) method.

FIG. 19 shows a cross-sectional view of an eighth composite obtained from grinding an outer periphery of the seventh composite.

FIG. 20 shows a cross-sectional view of a ninth composite after removing the stress layer, the graphite substrate, and the carbonized adhesive layer from the eighth composite through annealing treatment.

FIG. 21 shows a cross-sectional view of a SiC composite substrate.

FIG. 22 shows a perspective view of the SiC composite substrate (wafer).

FIG. 23 shows a cross-sectional view of a structure including a highly doped layer at the interface between the SiC epitaxial growth layer and the SiC polycrystalline growth layer.

FIG. 24 shows a cross-sectional view of a tenth composite in which a stress layer of a modified example is formed on the SiC epitaxial growth layer.

FIG. 25 shows a cross-sectional view of an eleventh composite in which a graphite substrate is attached onto the stress layer of the modified example of the tenth composite via an adhesive layer.

FIG. 26 shows a cross-sectional view of a twelfth composite in which the stress layer of the modified example of the tenth composite is attached to each of both surfaces of the graphite substrate via an adhesive layer.

FIG. 27 shows a cross-sectional view of a thirteenth composite in which the graphite substrate and the carbonized adhesive layer are removed from the twelfth composite through annealing treatment.

FIG. 28 shows a cross-sectional view of a Schottky barrier diode.

FIG. 29 shows a cross-sectional view of a trench gate type Trench Metal Oxide Semiconductor Field Effect Transistor (TMOSFET).

FIG. 30 shows a cross-sectional view of a planar gate type MOSFET.

### DETAILED DESCRIPTION OF THE EMBODIMENTS

Next, embodiments will be described with reference to the drawings. In the illustration of the drawings described below, the same or similar reference numerals are assigned to the same or similar parts. The drawings are schematic. In addition, the embodiments shown below are illustrative of devices and methods for embodying technical ideas, and do not specify the materials, shapes, structures, arrangements, etc. of components. Various modifications can be made to the embodiments.

### (Method for Manufacturing Semiconductor Substrate)

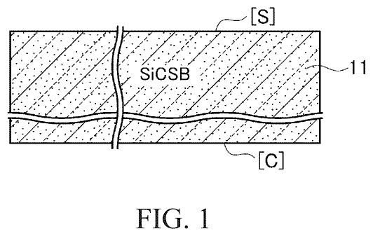

A method of manufacturing a semiconductor substrate according to an embodiment will be described. FIG. 1 is a cross-sectional view of a SiC monocrystalline substrate (SiCSB) 11 serving as a seed crystal substrate. There are crystallographic polymorphs in SiC, but the cubic crystal (3C) is called β-SiC, and the other high-temperature stable forms are called α-SiC. The SiC monocrystalline substrate 11 of the embodiment is, for example, a 4H—SiC substrate of α-SiC, and its thickness is, for example, between about 300 μm and about 600 μm. In addition, in FIG. 1, [C] represents a carbon (C) plane of SiC, and [S] represents a silicon (Si) plane of SiC. The same applies to the following drawings.

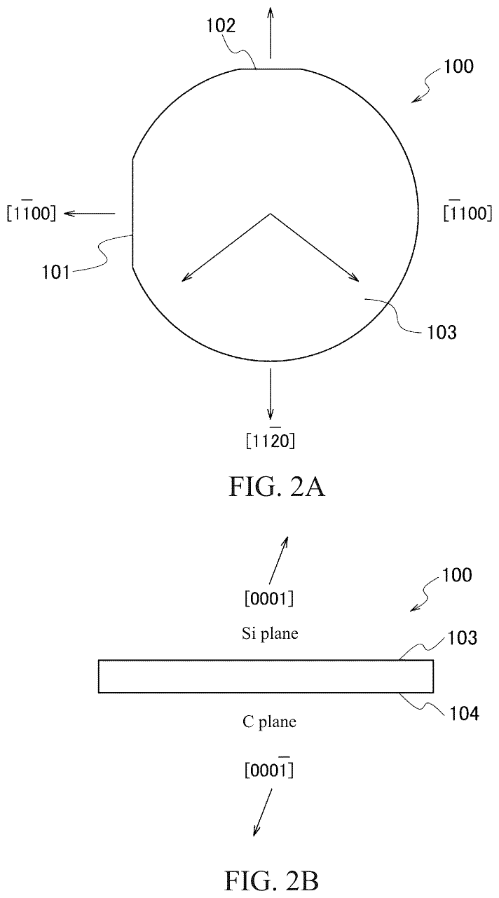

FIG. 2A and FIG. 2B are diagrams illustrating crystal planes of a SiC wafer 100 that can be used as the SiC monocrystalline substrate 11. The top view of FIG. 2A shows a Si plane 103 of the SiC wafer 100 on which a primary orientation flat 101 and a secondary orientation flat 102 are formed. In the side view viewed from the [−1100] orientation in FIG. 2B, the Si plane 103 with the [0001] orientation is formed on the upper surface, and the C plane 104 with the [000-1] orientation is formed on the lower surface.

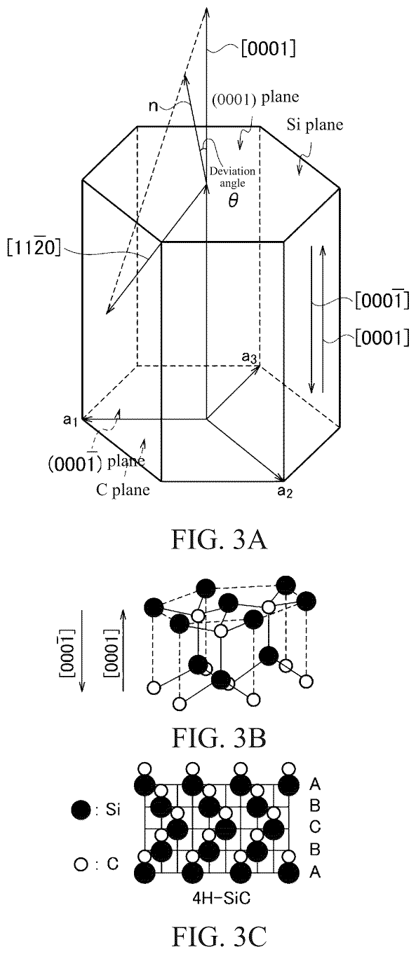

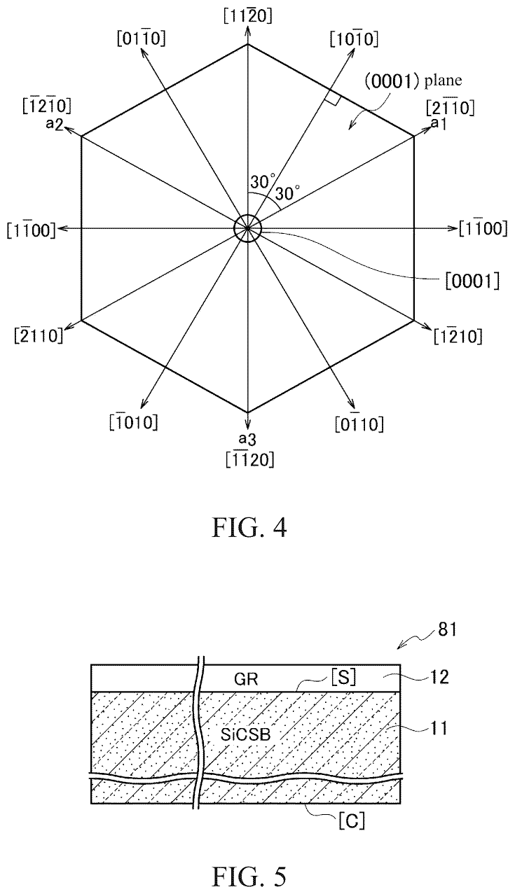

A schematic perspective view structure of a unit group of a 4H—SiC crystal applicable to the embodiment is shown in FIG. 3A. A schematic structure of a two-layer portion of the 4H—SiC crystal is shown in FIG. 3B. A schematic structure of a four-layer portion of the 4H—SiC crystal is shown in FIG. 3C. In addition, a schematic structure of the unit group of the 4H—SiC crystal structure shown in FIG. 3A is shown in FIG. 4 when viewed from directly above the (0001) plane.

As shown in FIGS. 3A to 3C, the crystal structure of 4H—SiC can be approximated by a hexagonal crystal system, with four C atoms bonded with one Si atom. The four C atoms are located at the four vertices of a regular tetrahedron with the Si atom placed in the center. Among these four C atoms, one C atom is located on the [0001] axis relative to the Si atom, and the other three C atoms are located on the [000-1] axis side relative to the Si atom. In FIG. 3A, the deviation angle θ is, for example, about 4 degrees or less.

The [0001] axis and the [000-1] axis are along the axial direction of the hexagonal prism, and the plane with the [0001] axis as the normal line (the top surface of the hexagonal prism) is the (0001) plane (Si plane). On the other hand, the plane with the [000-1] axis as the normal line (the lower surface of the hexagonal prism) is the (000-1) plane (C plane). In addition, the directions perpendicular to the [0001] axis and passing through the non-adjacent vertices of the hexagonal prism when viewed from directly above the (0001) plane are respectively the a1 axis [2-1-10], the a2 axis [−12-10] and the a3 axis [−1-120].

As shown in FIG. 4, the direction passing through the vertex between the a1 axis and the a2 axis is the [11-20] axis, the direction passing through the vertex between the a2 axis and the a3 axis is the [−2110] axis, and the direction passing through the vertex between the a3 axis and the a1 axis is the [1-210] axis. Between any adjacent two of the six axes passing through the vertexes of the hexagonal prism respectively, the axes inclined at an angle of 30° with respect to their adjacent axis on both sides and become the normal lines of the side surfaces of the hexagonal prism are [10-10] axis, [1-100] axis, [0-110] axis, [−1010] axis, [−1100] axis and [01-10] axis from between the a1 axis and [11-20] axis in clockwise order. The planes (the side surfaces of the hexagonal prism) with these axes as their normal lines respectively are the crystal planes at right angles to the (0001) plane and the (000-1) plane.

Next, as shown in FIG. 5, a graphene layer (GR) 12 with several molecular layers are stacked on the (0001) Si plane of the SiC monocrystalline substrate 11 to form a first composite 81. By annealing the SiC monocrystalline substrate 11 at about 1700° C. in, for example, an atmospheric pressure argon atmosphere, the graphene layer 12 can be formed by thermal decomposition of the Si plane of the SiC monocrystalline substrate 11. In addition, the graphene layer 12 may be formed and laminated on the SiC monocrystalline substrate 11 by chemical vapor deposition (CVD).

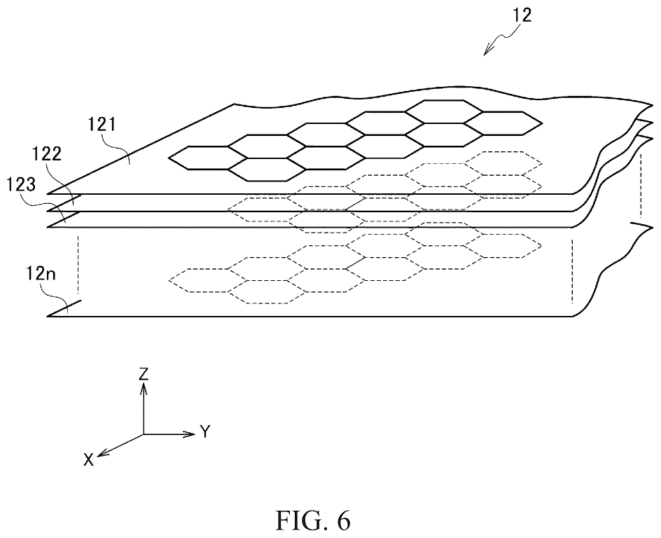

The graphene layer 12 applicable to the embodiment is shown as shown in FIG. 6. The graphene layer 12 has a laminated structure of graphite sheets 121, 122, 123 . . . 12n. Each plane of the n layers, including the graphite sheets 121, 122, 123 . . . 12n, has a plurality of covalent bonds of hexagonal carbon (C) in one laminated crystal structure. The graphite sheets 121, 122, 123 . . . 12n of the planes are combined through Van der Waals forces. In the embodiment, it may be a single-layer structure or a layer 0 for bonding a buffer layer to the SiC monocrystalline substrate 11.

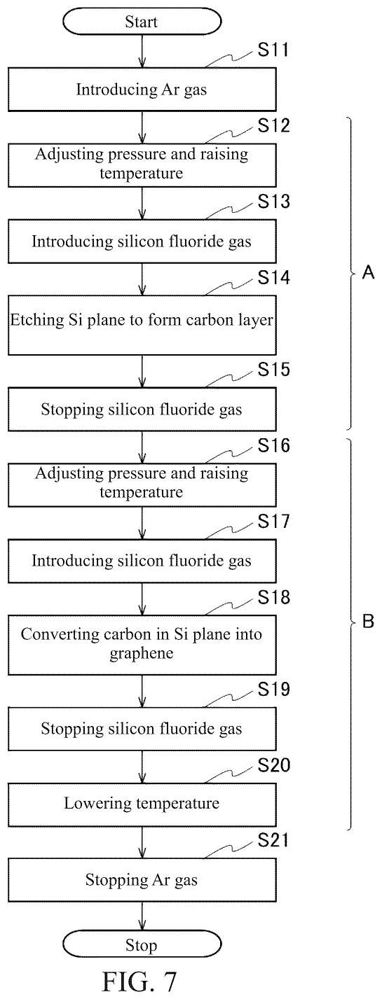

FIG. 7 is a flowchart showing a series of steps for forming the first composite 81 by laminating the graphene layer 12 on the Si plane of the SiC monocrystalline substrate 11.

### (Semiconductor Manufacturing Apparatus)

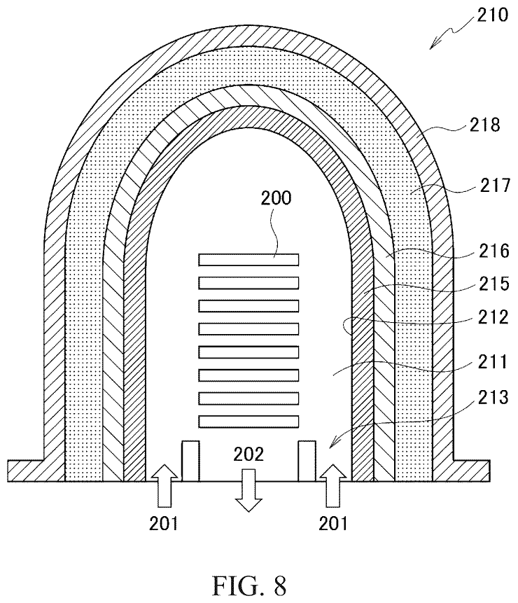

FIG. 8 is a reaction furnace 210 constituting a semiconductor manufacturing apparatus for film formation of the graphene layer 12 according to the embodiment. The reaction furnace 210 has a vertical tubular furnace chamber 211 capable of storing one to a plurality of film-forming substrates 200 stacked at predetermined intervals in the vertical direction on a supporter (not shown). From the inside of the furnace surface 212 toward the outside, the side and top of the furnace chamber 211 are surrounded in sequence by a base 215 of a mixed material, a carbon-based resistance heating heater and a resistance heating heater 216 having an infrared reflection plate of high melting point metals including tungsten (W), molybdenum (Mo), and tantalum (Ta), etc., a carbon-based heat insulating material 217, and a vacuum bell-type water-cooling chamber 218 made of metal such as stainless steel. The base 215 is made of a mixed material obtained by coating a silicon carbide ceramic or a graphite molded body with silicon carbide. The space between the base 215 and the water-cooling chamber 218 can be evacuated using a dry vacuum pump to improve thermal insulation. A gas supply hole for supplying gas 201 to the furnace chamber 211 and an exhaust hole for discharging the exhaust gas 202 from the furnace chamber 211 are formed in the bottom plate 213 of the furnace chamber 211. Because the furnace chamber 211 of the reaction furnace 210 extends tubularly in the vertical direction and can store more than one to multiple film-forming substrates 200 through a support and perform film-forming processing, it is also called a batch-type vertical tubular furnace.

The furnace chamber 211 can be heated from 1500° C. to 1800° C. In addition, in the furnace chamber 211, at least one of inert gases such as fluorine gas and argon gas, hydrocarbon gas, fluorocarbon gas, nitrogen gas, and hydrogen gas can be flowed at a constant flow rate, while the pressure of the internal space can be made independent and controlled to between 50 Pa and 50 kPa. Further, under the condition of no flowing gas, a turbine pump and a dry vacuum pump can be used to evacuate a high vacuum up to 1×10⁻⁵ Pa. In addition, there is a vacuum preload chamber that can store all the supports in the lower part of the furnace chamber 211 and is made of a material with high heat resistance at high temperature, that is, a preparation chamber that can be evacuated and a lifting mechanism for the supports. It has a structure that infinitely cuts off the intrusion of external air through these structures, and has an infrared heating heater in the vacuum preload chamber, so that the support and the film-forming substrate 200 mounted on the support can be heated to 100° C. or higher while a high vacuum up to 1×10⁻⁵ Pa can be created by using a turbine pump and a dry vacuum pump.

The SiC monocrystalline substrate 11 that becomes the film-forming substrate 200 in the reaction furnace 210 is cleaned in advance and then dried and stored in the furnace chamber 211. To clean the SiC monocrystalline substrate 11, a modified RCA method commonly used in semiconductor cleaning can be used. The furnace chamber 211 storing the SiC monocrystalline substrate 11 is evacuated to 1×10−5 Pa or less.

Referring to the flow chart of FIG. 7, the process of forming the graphene layer 12 on the SiC monocrystalline substrate 11 is roughly divided into the following procedures: a surface thermal etching A including steps S12 to S15, during which silicon in the Si plane of the SiC monocrystalline substrate is etched to leave carbon; and a surface thermal decomposition B including steps S16 to S20, during which the carbon remained after the sublimation of silicon in the Si plane of the SiC monocrystalline substrate 11 is crystallized to form the graphene layer 12.

Description will be given sequentially according to the flowchart of FIG. 7. In the first step S11, argon gas (Ar) serving as a carrier gas is supplied to the furnace chamber 211 of the reaction furnace 210. In step S12, the pressure of the atmosphere in the furnace chamber 211 is adjusted within the range of 100 Torr to 700 Torr, that is, the range of 13,000 Pa to 93,000 Pa, and the furnace chamber 211 is heated. The furnace chamber 211 can also be rapidly heated up at a speed of more than 50° C./second by using a rapid thermally-sensitive processor. The furnace chamber 211 can be heated by the resistance heating heater 216 provided in the reaction furnace 210, and can be heated by infrared irradiation simultaneously. Further, high-frequency induction heating and infrared irradiation heating can also be used. Alternatively, rapid heating may be performed by transporting the SiC monocrystalline substrate 11 in the furnace chamber 211 that has been heated to a high temperature.

After the temperature of the furnace chamber 211 reaches 1400° C. from 1200° C., the process proceeds to step S13 and silicon fluoride gas is introduced into the furnace chamber 211. In step S14, silicon (Si) in the Si plane of the SiC monocrystalline substrate 11 is selectively etched with silicon fluoride gas to form a carbon (C) layer.

Here, from the viewpoint of reaction Gibbs energy, active species suitable for selectively etching Si in the Si plane of the SiC monocrystalline substrate 11 to form a C layer are studied. First, the reactivity of graphene (C) with various active species is studied. Tables 1 to 4 show the reaction Gibbs energy Gr based on the reaction formulas between graphene and chlorine (Cl₂), hydrogen chloride (HCl), hydrogen (H₂), and silicon tetrafluoride (SiF₄) respectively. In each table, the standard enthalpy of formation AH, the standard entropy S, and the standard Gibbs energy of formation Gf corresponding to each substance in the reaction formula are also shown. The values of the standard Gibbs energy of formation Gf and the reaction Gibbs energy Gr at 25° C. and 1500° C. are shown.

TABLE 1

| | | | | | | |
|---|---|---|---|---|---|---|
| Reaction | 2 | C (Gr) + | 2 | Cl2 (g) → | 2 | CCI * (g) |

| [symbol] H(kJ/mol) | | 0 | 0 | 502.08 |
|---|---|---|---|---|
| S (J/K · mol) | | 5.74 | 222.957 | 224.41 |
| Gf (kd/mol) = | 25° C. | −1.71 | −66.44 | 435.21 |
| H-TS | 1500° C. | −10.18 | −395.30 | 104.20 |

| | | |
|---|---|---|
| Gr (kJ/mol) = | 25° C. | 1006.7 |
| right − left | 1500° C. | 1019.4 |

TABLE 2

| | | | | | | |
|---|---|---|---|---|---|---|
| Reaction | 1 | C (Gr) + | 2 | HCl (g) → | 1 | CH2Cl2 |

| [symbol] H(kJ/mol) | | 0 | −92.307 | −95.52 |
|---|---|---|---|---|
| S (J/K · mol) | | 5.74 | 186.799 | 270.17 |
| Gf (kJ/mol) = | 25° C. | −1.71 | −147.97 | −176.03 |
| H-TS | 1500° C. | −10.18 | −423.50 | −574.53 |

| | | |
|---|---|---|
| Gr (kJ/mol) = | 25° C. | 121.6 |
| right − left | 1500° C. | 282.6 |

TABLE 3

| | | | | | | |
|---|---|---|---|---|---|---|
| Reaction | 2 | C (Gr) + | 1 | H2 (g) → | 1 | C2H2 |

| [symbol] H (kJ/mol) | | 0 | 0 | 226.73 |
|---|---|---|---|---|
| S(J/K · mol) | | 5.74 | 130.575 | 200.82 |
| Gf (kJ/mol) = | 25° C. | −1.71 | −38.91 | 166.89 |
| H-TS | 1500° C. | −10.18 | −231.51 | −129.32 |

| | | |
|---|---|---|
| Gr (kJ/mol) = | 25° C. | 209.2 |
| right − left | 1500° C. | 122.5 |

TABLE 4

| | | | | | | | | |
|---|---|---|---|---|---|---|---|---|
| Reaction | 1 | C (Gr) + | 1 | SiF4 (g) → | 1 | CF4 (g) + | 1 | Si (g) |

| [symbol] H (kJ/mol) | | 0 | −1614.94 | 226.73 | 450.6 |
|---|---|---|---|---|---|
| S (J/K · mol) | | 5.74 | 282.38 | 200.82 | 167.868 |
| Gf (kJ/ | 25° C. | −1.71 | −1699.09 | 166.89 | 400.58 |
| mol) = | 1500° C. | −10.18 | −2115.60 | −129.32 | 152.97 |
| H-TS | | | | | |

| | | |
|---|---|---|
| Gr (kJ/ | 25° C. | 2268.3 |
| mol) = | 1500° C. | 2149.4 |
| right − left | | |

Referring to Tables 1 to 4, it is observed that the reaction Gibbs energies Gr at 1500° C. are all positive and increase in order according to H₂, HCl, Cl₂ and SiF₄, with the values with respect to H₂ and HCl being relatively close. Based on these results, it is estimated that their reactivity with graphene (C) is ranked in the following order.

$${H}_{2} ≧ H C 1 > C {1}_{2} > S i {F}_{4}$$

Similarly, for silicon (Si), the reactivity with various active species is also studied based on the reaction Gibbs energy. Tables 5 to 8 show the reaction Gibbs energy Gr based on the reaction formulas between silicon and chlorine (Cl₂), hydrogen chloride (HCl), hydrogen (H₂), and silicon tetrafluoride (SiF₄) respectively.

TABLE 5

| Reaction | | 2 Si (s) + | Cl2 (g) → | 2 SiCl2 (g) |
|---|---|---|---|---|
| [symbol] H (kJ/mol) | | 0 | 0 | −165.64 |
| S (J/K · mol) | | 18.83 | 222.957 | 280.3 |
| Gf (kJ/mol) = | 25° C. | −5.61 | −66.44 | −249.17 |
| H-TS | 1500° C. | −33.39 | −395.30 | −662.61 |

| | | |
|---|---|---|
| Gr (kJ/mol) = | 25° C. | −420.7 |
| right − left | 1500° C. | −863.1 |

TABLE 6

| | | | | | | | | |
|---|---|---|---|---|---|---|---|---|
| Reaction | 1 | Si (s) + | 2 | HCl (g) → | 2 | SiCl2 (g) | 1 | H2 (g) |

| [symbol] H (kJ/mol) | | 0 | −92.307 | −165.64 | 0 |
|---|---|---|---|---|---|
| S (J/K · mol) | | 5.74 | 186.799 | 280.3 | 130.575 |
| Gf (kJ/ | 25° C. | −1.71 | −147.97 | −249.17 | −38.91 |
| mol) = | 1500° C. | −10.18 | −423.50 | −662.61 | −231.51 |
| H-TS | | | | | |

| | | |
|---|---|---|
| Gr (kJ/ | 25° C. | −239.6 |
| mol) = | 1500° C. | −699.6 |
| right − left | | |

TABLE 7

| | | | | | | |
|---|---|---|---|---|---|---|
| Reaction | 1 | Si (s) + | 2 | H2 (g) → | 1 | SiH4 (g) |

| [symbol] H (kJ/mol) | | 0 | 0 | 34.3 |
|---|---|---|---|---|
| S (J/K · mol) | | 5.74 | 130.575 | 204.51 |
| Gf (kJ/mol) = | 25° C. | −1.71 | −38.91 | −26.64 |
| H-TS | 1500° C. | −10.18 | −231.51 | −328.30 |

| | | |
|---|---|---|
| Gr (kJ/mol) = | 25° C. | 52.9 |
| right − left | 1500° C. | 144.9 |

TABLE 8

| | | | | | | | | |
|---|---|---|---|---|---|---|---|---|
| Reaction | 2 | Si(s) | 2 | SiF4(g) → | 2 | Si2F6(g)+ | 1 | F2(g) |

| [symbol] H(kJ/mol) | | 0 | −1614.94 | −2383.29 | 0 |
|---|---|---|---|---|---|
| S(J/K · mol) | | 5.74 | 282.38 | 390.983 | 202.67 |
| Gf(kJ/ | 25° C. | −1.71 | −1699.09 | −2499.80 | −60.40 |
| mol) = | 1500° C. | −10.18 | −2115.60 | −3076.50 | −359.33 |
| H-TS | | | | | |

| | | |
|---|---|---|
| Gr(kJ/ | 25° C. | −1658.4 |
| mol) = | 1500° C. | −2260.8 |
| right − | | |
| left | | |

Referring to Tables 5 to 8, it is observed that the reaction Gibbs energy Gr at 1500° C. is positive in H₂, but negative in HCl, Cl₂, and SiF₄, and increases in order according to SiF₄, Cl₂, HCl, and H₂. Based on these results, it is estimated that their reactivity with Si is ranked in the following order.

$$S i {F}_{4} > C {1}_{2} > H C 1 > {H}_{2}$$

Substances that easily cause graphene etching are also studied from the viewpoint of reaction Gibbs energy. Tables 9 to 14 below show the reaction Gibbs energy Gr for graphene, based on the reaction formulas with water (H₂O), hydroxyl radical (OH), oxygen (O₂), nitrogen (N₂), hydrogen fluoride (HF), dichlorosilane (SiH₂Cl₂), chlorine (Cl₂), hydrogen chloride (HCl), hydrogen (H₂), silicon tetrafluoride (SiF₄), methane (CH₄) and monosilane (SiH₄) respectively.

TABLE 9

| | | | | | | | | |
|---|---|---|---|---|---|---|---|---|
| Reaction | 1 | C (Gr) + | 1 | H2O (g) → | 1 | CO (g) + | 1 | H2 (g) |

| [symbol] H (kJ/mol) | | 0 | −241.826 | −110.525 | 0 |
|---|---|---|---|---|---|
| S(J/K · mol) | | 5.74 | 188.723 | 197.565 | 130.575 |
| Gf (kJ/ | 25° C. | −1.71 | −298.07 | −169.40 | −38.91 |
| mol) = | 1500° C. | −10.18 | −576.43 | −460.81 | −231.51 |
| H-TS | | | | | |

| | | |
|---|---|---|
| Gr (kJ/ | 25° C. | 91.5 |
| mol) = | 1500° C. | −105.7 |
| right − left | | |

TABLE 10

| | | | | | | | | |
|---|---|---|---|---|---|---|---|---|
| Reaction | 1 | C (Gr) + | 1 | OH (g) → | 1 | CO (g) + | 1 | H (g) |

| [symbol] H (kJ/mol) | | 0 | 38.95 | −110.525 | 217.965 |
|---|---|---|---|---|---|
| S(J/K · mol) | | 5.74 | 183.636 | 197.565 | 114.604 |
| Gf (kJ/ | 25° C. | −1.71 | −15.77 | −169.40 | 183.81 |
| mol) = | 1500° C. | −10.18 | −286.64 | −460.81 | 14.77 |
| H-TS | | | | | |

| | | |
|---|---|---|
| Gr (kJ/ | 25° C. | 31.9 |
| mol) = | 1500° C. | −149.2 |
| right − left | | |

TABLE 11

| | | | | | | |
|---|---|---|---|---|---|---|
| Reaction | 2 | C(Gr)+ | 1 | O2(g)→ | 2 | CO2(g) |

| [symbol] H(kJ/mol) | | 0 | −92.307 | −110.525 |
|---|---|---|---|---|
| S(J/K · mol) | | 5.74 | 186.799 | 197.565 |
| Gf(kJ/mol) = | 25° C. | −1.71 | −147.97 | −169.40 |
| H − TS | 1500° C. | −10.18 | −423.50 | −460.81 |

| | | |
|---|---|---|
| Gr(kJ/mol) = | 25° C. | −187.4 |
| right − left | 1500° C. | −477.8 |

TABLE 12

| | | | | | | |
|---|---|---|---|---|---|---|
| Reaction | 2 | C(Gr)+ | 1 | N2(g)→ | 2 | (CN)2(g) |

| [symbol] H(kJ/mol) | | 0 | −92.307 | 309.1 |
|---|---|---|---|---|
| S(J/K · mol) | | 5.74 | 186.799 | 242.09 |
| Gf(kJ/mol) = | 25° C. | −1.71 | −147.97 | 236.96 |
| H − TS | 1500° C. | −10.18 | −423.50 | −120.13 |

| | | |
|---|---|---|
| Gr(kJ/mol) = | 25° C. | 625.3 |
| right − left | 1500° C. | 203.6 |

TABLE 13

| | | | | | | |
|---|---|---|---|---|---|---|
| Reaction | 1 | C(Gr)+ | 2 | HF(g)→ | 1 | CH2F2 |

| [symbol] H(kJ/mol) | | 0 | −271.1 | −450.66 |
|---|---|---|---|---|
| S(J/K · mol) | | 5.74 | 173.67 | 246.59 |
| Gf(kJ/mol) = | 25° C. | −1.71 | −322.85 | −524.14 |
| H − TS | 1500° C. | −10.18 | −579.02 | −887.86 |

| | | |
|---|---|---|
| Gr(kJ/mol) = | 25° C. | 123.3 |
| right − left | 1500° C. | 280.3 |

TABLE 14

| | | | | | | | | |
|---|---|---|---|---|---|---|---|---|
| Reaction | 1 | C(Gr)+ | 2 | SiH2Cl2(g)→ | 2 | SiCl2(g)+ | 1 | CH4(g) |

| [symbol] H(kJ/mol) | | 0 | −320.5 | −165.64 | −74.87 |
|---|---|---|---|---|---|
| S(J/K · mol) | | 5.74 | 285.6 | 280.3 | 186.14 |
| Gf(kJ/mol) = | 25° C. | −1.71 | −405.61 | −249.17 | −130.34 |
| H − TS | 1500° C. | −10.18 | −826.87 | −662.61 | −404.90 |

| | | |
|---|---|---|
| Gr(kJ/mol) = | 25° C. | 184.2 |
| right − left | 1500° C. | −66.2 |

TABLE 15

| | | | | | | |
|---|---|---|---|---|---|---|
| Reaction | 2 | C(Gr)+ | 1 | Cl2(g)→ | 2 | CCl*(g) |

| [symbol] H(kJ/mol) | | 0 | 0 | 502.08 |
|---|---|---|---|---|
| S(J/K · mol) | | 5.74 | 222.957 | 224.41 |
| Gf(kJ/mol) = | 25° C. | −1.71 | −66.44 | 435.21 |
| H − TS | 1500° C. | −10.18 | −395.30 | 104.20 |

| | | |
|---|---|---|
| Gr(kJ/mol) = | 25° C. | 940.3 |
| right − left | 1500° C. | 624.1 |

TABLE 16

| | | | | | | |
|---|---|---|---|---|---|---|
| Reaction | 1 | C(Gr)+ | 2 | HCl(g)→ | 1 | CH2Cl2 |

| [symbol] H(kJ/mol) | | 0 | −92.307 | −95.52 |
|---|---|---|---|---|
| S(J/K · mol) | | 5.74 | 186.799 | 270.17 |
| Gf(kJ/mol) = | 25° C. | −1.71 | −147.97 | −176.03 |
| H − TS | 1500° C. | −10.18 | −423.50 | −574.53 |

| | | |
|---|---|---|
| Gr(kJ/mol) = | 25° C. | 121.6 |
| right − left | 1500° C. | 282.6 |

TABLE 17

| | | | | | | |
|---|---|---|---|---|---|---|
| Reaction | 2 | C(Gr)+ | 1 | H2(g)→ | 1 | C2H2 |

| [symbol] H(kJ/mol) | | 0 | 0 | 226.73 |
|---|---|---|---|---|
| S(J/K · mol) | | 5.74 | 130.575 | 200.82 |
| Gf(kJ/mol) = | 25° C. | −1.71 | −38.91 | 166.89 |
| H − TS | 1500° C. | −10.18 | −231.51 | −129.32 |

| | | |
|---|---|---|
| Gr(kJ/mol) = | 25° C. | 209.2 |
| right − left | 1500° C. | 122.5 |

TABLE 18

| | | | | | | | | |
|---|---|---|---|---|---|---|---|---|
| Reaction | 1 | C(Gr)+ | 1 | SiF4(g)→ | 1 | CF4(g)+ | 1 | Si(g) |

| [symbol] H(kJ/mol) | | 0 | −1614.94 | 226.73 | 450.6 |
|---|---|---|---|---|---|
| S(J/K · mol) | | 5.74 | 282.38 | 200.82 | 167.868 |
| Gf(kJ/mol) = | 25° C. | −1.71 | −1699.09 | 166.89 | 400.58 |
| H − TS | 1500° C. | −10.18 | −2115.60 | −129.32 | 152.97 |

| | | |
|---|---|---|
| Gr(kJ/mol) = | 25° C. | 2268.3 |
| right − left | 1500° C. | 2149.4 |

TABLE 19

| | | | | | | |
|---|---|---|---|---|---|---|
| Reaction | 1 | C(Gr)+ | 3 | CH4(g)→ | 2 | C2H6(g)+ |

| [symbol] H(kJ/mol) | | 0 | −74.87 | −83.8 |
|---|---|---|---|---|
| S(J/K · mol) | | 5.74 | 186.14 | 229.1 |
| Gf(kJ/mol) = | 25° C. | −1.71 | −130.34 | −152.07 |
| H − TS | 1500° C. | −10.18 | −404.90 | −489.99 |

| | | |
|---|---|---|
| Gr(kJ/mol) = | 25° C. | 88.6 |
| right − left | 1500° C. | 244.9 |

TABLE 20

| | | | | | | | | |
|---|---|---|---|---|---|---|---|---|
| Reaction | 1 | C(Gr)+ | 1 | SiH4(g)→ | 1 | CH4(g)+ | 1 | Si(s) |

| [symbol] H(kJ/mol) | | 0 | 34.3 | −74.87 | 0 |
|---|---|---|---|---|---|
| S(J/K · mol) | | 5.74 | 204.51 | 186.14 | 18.83 |
| Gf(kJ/mol) = | 25° C. | −1.71 | −26.64 | −130.34 | −5.61 |
| H − TS | 1500° C. | −10.18 | −328.30 | −404.90 | −33.39 |

| | | |
|---|---|---|
| Gr(kJ/mol) = | 25° C. | −107.6 |
| right − left | 1500° C. | −99.8 |

Referring to Table 9 to Table 12, it is observed that the reaction Gibbs energy Gr at 1500° C. is negative in O₂, OH, H₂O, SiH₄ and SiH₂Cl₂ and increases in order, is positive in H₂, N₂, CH₄, HF, HCl, Cl₂ and SiF₄ and increase in order, among which the values for H₂, N₂, CH₄ and HF are relatively close, and the values for HF and HCl are almost the same. Therefore, it is estimated that the reactivity of each of the above substances with graphene is ranked in the following order.

$${O}_{2} > O H > {H}_{2} O > S i {H}_{4} > S i {H}_{2} C {1}_{2} > {H}_{2} ≧ {N}_{2} ≧ C {H}_{4} ≧ H F =$$

$$H C 1 > C {1}_{2} > S i {F}_{4}$$

In order to selectively etch the silicon (Si) in the Si plane of the SiC monocrystalline substrate 11 and form the carbon (C) layer, a substance with high reactivity with Si and low reactivity with graphene is suitable. After studying chemical reactivity from the perspective of the reaction Gibbs energy Gr, it is determined that silicon tetrafluoride (SiF₄) is fit for such a substance. It is contemplated that not only silicon tetrafluoride, but other silicon fluorides such as disilicon hexafluoride (Si₂F₆) with similar chemical properties can also be used.

In addition, higher-order silicon fluoride gases with order higher than trisilicon octafluoride (Si₃F₈) have the properties that the higher the order of compound, the lower the thermal decomposition temperature, and the easier it is to release Si atoms and fluorine atoms. For the formation of carbon layer, though a mechanism that selectively etches Si from the surface of the SiC substrate with fluorine atoms to leave carbon is used, the high-order silicon fluoride gas excessively increases the Si partial pressure or vapor pressure in the gas phase, so it is easy to cause a reaction called Si vapor pressure etching, that is, the remaining carbon reacts with Si to cause a secondary reaction, which makes Si₂C or SiC₂ become sublimating compounds. As a result, carbon is easily etched away and disappears, and is difficult to be controlled. For this reason, in the embodiment, it is limited to use of low-order silicon fluoride gases up to disilicon hexafluoride gas in view of practicality.

In addition, although chlorine (Cl₂) has properties close to silicon tetrafluoride (SiF₄), when being used to form a carbon layer, the reaction Gibbs energy of Cl₂ for carbon etching is 624 KJ/mol. In contrast, it is 2149 KJ/mol for SiF₄. Because the carbon layer needs to be controlled at the atomic level, Cl₂ is difficult to be used and is considered unsuitable.

Returning to step S13 in FIG. 7, in the reaction furnace 210 called a batch-type vertical tubular furnace, since the uniform heating length in the furnace chamber 211 is relatively long, it is considered that SiF₄ is thermally decomposed in the furnace chamber 211 gradually. For the silicon fluoride, it may use the Si₂F₆ monomer alone or a mixed gas of SiF₄ and Si₂F₆ with an adjusted mixing ratio.

In step S14, the silicon fluoride gas introduced into the furnace chamber 211 in step S13 thermally etches the Si plane of the SiC monocrystalline substrate 11 to form the carbon layer. The etched amount of the Si plane is controlled by the introduction time and temperature of silicon fluoride, and the temperature and gas exposure time conditions are set according to the target number of graphene layers formed. When the desired etched amount and the number of graphene layers are reached, the supply of silicon fluoride gas to the furnace chamber 211 is stopped in step S15.

After the Si plane of the SiC monocrystalline substrate 11 is etched to form the carbon layer through the procedure of the surface thermal etching A including step S12 to step S15, the carbon remained from the sublimation of silicon in the Si plane of the SiC monocrystalline substrate 11 is crystallized to form the graphene layer 12 through the procedure of the surface thermal decomposition B including step S16 to step S20.

In step S16, the pressure of the Ar gas atmosphere supplied to the furnace chamber 211 is readjusted to 700 Torr, that is, 93,000 Pa, and the temperature of the furnace chamber 211 is heated from 1650° C. to 1700° C. Similar to step S12, a rapid thermally-sensitive processor can also be used to rapidly raise the temperature at a speed of 100° C./second or more. In addition, similar to step S12, the furnace chamber 211 can be heated by the resistance heating heater 216 provided in the reaction furnace 210, and can be heated by infrared irradiation simultaneously. Further, high-frequency induction heating and infrared irradiation heating can also be used. Alternatively, rapid heating may be performed by transporting the SiC monocrystalline substrate 11 in the furnace chamber 211 that has been heated to a high temperature.

In this way, step-bunching of the SiC monocrystalline substrate 11 toward the Si layer surface is suppressed to a minimum by rapidly heating the SiC monocrystalline substrate 11 in step S16. By quickly forming a low-defect layer 0 (a buffer layer) at this stage, it is possible to suppress the sublimation of silicon (Si) to a minimum and maintain a smooth surface with little progress in bunching.

After the temperature of the furnace chamber 211 reaches 1700° C. from 1650° C., the process proceeds to step S17, where silicon fluoride gas is introduced into the furnace chamber 211. As mentioned above, in the reaction furnace 210 called the batch-type vertical tubular furnace, since the uniform heating length in the furnace chamber 211 is relatively long, it is contemplated that SiF₄ is gradually thermally decomposed in the furnace chamber 211. For the silicon fluoride, it may use the Si₂F₆ monomer alone or a mixed gas of SiF₄ and Si₂F₆ with an adjusted mixing ratio.

In step S18, the Si plane of the SiC monocrystalline substrate 11 is thermally decomposed by silicon fluoride gas to sublime silicon (Si), and the remaining carbon layer is crystallized and converted into a graphene layer. In this way, the first composite 81 in which the graphene layer is laminated on the Si plane of the SiC monocrystalline substrate 11 is formed. When the grapheneization of the carbon layer is completed, the process proceeds to step S17 and the supply of silicon fluoride gas is stopped. In addition, the temperature of the furnace chamber 211 is lowered in step S20, and the supply of Ar gas is stopped in step S21. Afterwards, the first composite 81 is taken out from the furnace chamber 211.

In this way, after the Si plane of the SiC monocrystalline substrate 11 is etched through the surface thermal etching A including steps S12 to step S15 to form the carbon layer, the procedure of surface thermal decomposition B including steps S16 to S20, during which the carbon remaining from the sublimation of silicon in the Si plane of the SiC monocrystalline substrate 11 is crystallized to form the graphene layer 12, is performed, thereby forming the first composite 81, in which the graphene layer is laminated on the Si plane of the SiC monocrystalline substrate 11.

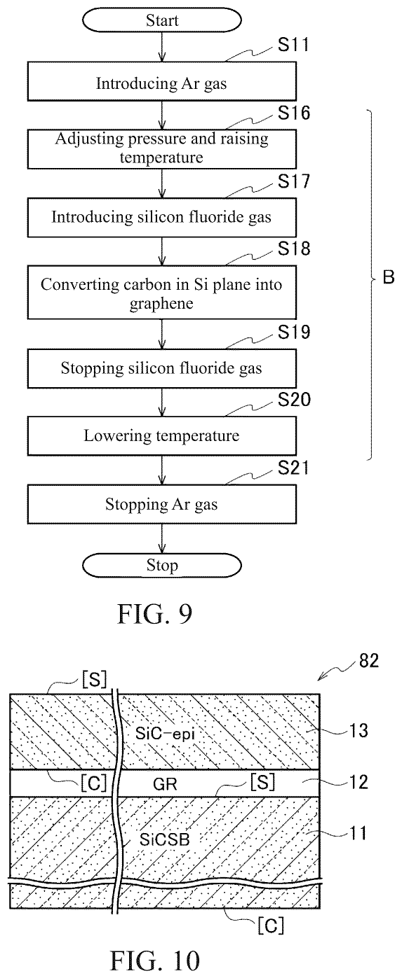

FIG. 9 is a flowchart showing a series of steps in a modified example of forming the first composite 81 by laminating the graphene layer 12 on the Si plane of the SiC monocrystalline substrate 11. In the series of steps of forming the graphene layer shown in FIG. 7, the procedure of the surface thermal etching A including step S12 to step S15 is omitted, and the procedure of the surface thermal decomposition B including step S16 to step S20, during which the carbon remaining from the sublimation of silicon in the Si plane of the SiC monocrystalline substrate 11 is crystallized to form the graphene layer 12, is included.

The process will be explained sequentially according to the flowchart of FIG. 9. In the series of steps in FIG. 9, steps corresponding to the steps from S11 to S21 shown in FIG. 7 are denoted by common reference numerals, and detailed descriptions thereof are omitted. In step S11, Ar gas serving as a carrier gas is supplied to the furnace chamber 211 of the reaction furnace 210. In step S16, the pressure of the Ar gas atmosphere supplied to the furnace chamber 211 is readjusted to 700 Torr, that is, 93,000 Pa, and the temperature of the furnace chamber 211 is heated from 1650° C. to 1700° C.

After the temperature of the furnace chamber 211 reaches 1700° C. from 1650° C., the process proceeds to step S17, where silicon fluoride gas is introduced into the furnace chamber 211. For the silicon fluoride, it may use the Si₂F₆ monomer alone or a mixed gas of SiF₄ and Si₂F₆ with an adjusted mixing ratio. In step S18, the Si plane of the SiC monocrystalline substrate 11 is thermally decomposed by silicon fluoride gas to sublime silicon (Si), and the remaining carbon layer is crystallized and converted into a graphene layer. The graphene layer may be a single layer or a layer 0 (a buffer layer). Proceeding to step S19, the supply of silicon fluoride gas is stopped, and the temperature of the furnace chamber 211 is lowered in step S20. In step S21, the supply of Ar gas is stopped, and then the first composite 81 with the graphene layer laminated on the Si plane of the SiC monocrystalline substrate 11 is taken out from the furnace chamber 211.

Next, as shown in FIG. 10, a SiC epitaxial growth layer (SiC-epi) 13 is laminated on the graphene layer 12 of the first composite 81 shown in FIG. 5 to form a second composite 82. The SiC epitaxial growth layer 13 is formed on the graphene layer 12 formed on the Si plane of the SiC monocrystalline substrate 11 by the van der Waals epitaxial growth method. The SiC epitaxial growth layer 13 is a monocrystalline SiC thin film of α-SiC. A surface of the SiC epitaxial growth layer 13 in contact with the graphene layer 12 becomes a C plane, and another surface of the SiC epitaxial growth layer 13 becomes a Si plane.

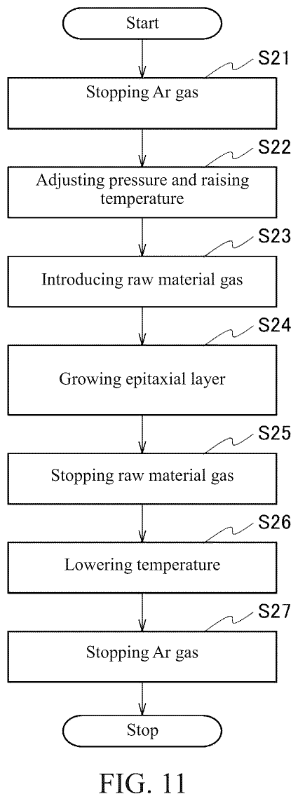

FIG. 11 is a flowchart showing a series of steps for forming the second composite 82 by laminating the SiC epitaxial growth layer 13 on the graphene layer 12 of the first composite 81. In this series of steps, the semiconductor manufacturing apparatus according to the embodiment, that is, the reaction furnace 210 is also used.

The film-forming substrate 200 in the reaction furnace 210 is the first composite 81 in which the graphene layer 12 is laminated on the Si plane of the SiC monocrystalline substrate 11. The graphene layer 12 may be a single layer or a layer 0 (a buffer layer). The furnace chamber 211 storing the first composite 81 is evacuated to 1×10⁻⁵ Pa or less.

In the first step S21, Ar gas serving as a carrier gas is supplied to the furnace chamber 211 of the reaction furnace 210. In step S22, the atmosphere pressure of the furnace chamber 211 is adjusted to about 800 Torr, that is, about 110,000 Pa, and the atmosphere is heated from 1,500° C. to 1,600° C. The temperature is determined based on the desired growth rate and film quality. In the first composite 81, the Si plane of the SiC monocrystalline substrate 11 is covered by the graphene layer 12, and the graphene layer 12 suppresses the sublimation of Si without step-bunching. Therefore, rapid heating is not needed, and the resistance heating heater 216 provided in the reaction furnace can also be used for heating.

After the temperature of the furnace chamber 211 reaches 1,600° C. from 1,500° C., silicon fluoride gas together with hydrocarbon gas or carbon fluoride gas are introduced into the furnace chamber 211 in step S23, serving as the material gases for forming the SiC epitaxial growth layer 13. In step S24, the SiC epitaxial growth layer 13 is formed on the Si plane of the SiC monocrystalline substrate 11 using these material gases through van der Waals growth with the graphene layer 12 interposed therebetween.

Here, from the viewpoint of reaction Gibbs energy, types of material gases suitable for forming a SiC epitaxial growth layer are studied. First, the reactivity of silicon tetrafluoride (SiF₄) with various fluorocarbons is studied. Tables 21 to 25 show the reaction Gibbs energies Gr based on the reaction formulas of SiF₄ with tetrafluoromethane (CF₄), hexafluoroethane (C₂F₆), octafluoropropane (C₃F₈), tetrafluoroethylene (C₂F₄) and fluorinated acetylene (C₂HF) respectively.

TABLE 21

| | | | | | | | | | |
|---|---|---|---|---|---|---|---|---|---|
| Reaction | 1 | CF4(g)+ | 1 | SiF4(g)→ | 1 | α-SiC(s)+ | 0 | 4 | F2(g) |

| [symbol] H(kJ/mol) | | −930 | −1614.94 | −62.8 | | 0 |
|---|---|---|---|---|---|---|
| S(J/K · mol) | | 261.3 | 282.38 | 16.602 | | 202.67 |
| Gf(kJ/mol) = | 25° C. | −1007.87 | −1699.09 | −67.75 | 0.00 | −60.40 |
| H − TS | 1500° C. | −1393.28 | −2115.60 | −92.24 | 0.00 | −359.33 |

| | | |
|---|---|---|
| Gr(kJ/mol) = | 25° C. | 2397.6 |
| right − left | 1500° C. | 1979.3 |

TABLE 22

| | | | | | | | | | |
|---|---|---|---|---|---|---|---|---|---|
| Reaction | 1 | C2F6(g)+ | 2 | SiF4(g)→ | 2 | α-SiC(s)+ | 0 | 5 | F2(g) |

| [symbol] H(kJ/mol) | | −1343.9 | −1614.94 | −62.8 | | 0 |
|---|---|---|---|---|---|---|
| S(J/K · mol) | | 331.98 | 282.38 | 16.602 | | 202.67 |
| Gf(kJ/mol) = | 25° C. | −1442.83 | −1699.09 | −67.75 | 0.00 | −60.40 |
| H − TS | 1500° C. | −1932.50 | −2115.60 | −92.24 | 0.00 | −359.33 |

| | | |
|---|---|---|
| Gr(kJ/mol) = | 25° C. | 2201.8 |
| right − left | 1500° C. | 2091.3 |

TABLE 23

| | | | | | | | | | |
|---|---|---|---|---|---|---|---|---|---|
| Reaction | 1 | C3F8(g)+ | 3 | SiF4(g)→ | 3 | α-SiC(s)+ | 0 | 6 | F2(g) |

| [symbol] H(kJ/mol) | | −1783.2 | −1614.94 | −62.8 | | 0 |
|---|---|---|---|---|---|---|
| S(J/K · mol) | | 0 | 282.38 | 16.602 | | 202.67 |
| Gf(kJ/mol) = | 25° C. | −1783.20 | −1699.09 | −67.75 | 0.00 | −60.40 |
| H − TS | 1500° C. | −1783.20 | −2115.60 | −92.24 | 0.00 | −359.33 |

| | | |
|---|---|---|
| Gr(kJ/mol) = | 25° C. | 2105.0 |
| right − left | 1500° C. | 1899.1 |

TABLE 24

| | | | | | | | | | |
|---|---|---|---|---|---|---|---|---|---|
| Reaction | 1 | C2F4(g)+ | 2 | SiF4(g)→ | 2 | α-SiC(s)+ | 0 | 4 | F2(g) |

| [symbol] H(kJ/mol) | | −12.43 | −1614.94 | −62.8 | | 0 |
|---|---|---|---|---|---|---|
| S(J/K · mol) | | 343.31 | 282.38 | 16.602 | | 202.67 |
| Gf(kJ/mol) = | 25° C. | −114.74 | −1699.09 | −67.75 | 0.00 | −60.40 |
| H − TS | 1500° C. | −621.12 | −2115.60 | −92.24 | 0.00 | −359.33 |

| | | |
|---|---|---|
| Gr(kJ/mol) = | 25° C. | 1567.9 |
| right − left | 1500° C. | 1615.3 |

TABLE 25

| | | | | | | | | | | |
|---|---|---|---|---|---|---|---|---|---|---|
| Reaction | 1 | C2HF(g)+ | 2 | SiF4(g)→ | 2 | α-SiC(s)+ | 1 | HF(g) | 2 | F2(g) |

| [symbol] H(kJ/mol) | | 125.52 | −1614.94 | −62.8 | −271.1 | 0 |
|---|---|---|---|---|---|---|
| S(J/K · mol) | | 231.5 | 282.38 | 16.602 | 173.67 | 202.67 |
| Gf(kJ/mol) = | 25° C. | 56.53 | −1699.09 | −67.75 | −322.85 | −60.40 |
| H − TS | 1500° C. | −284.93 | −2115.60 | −92.24 | −579.02 | −359.33 |

| | | |
|---|---|---|
| Gr(kJ/mol) = | 25° C. | 1381.3 |
| right − left | 1500° C. | 1517.0 |

As shown in Tables 21 to 25, all the reaction Gibbs energies at 1500° C. based on the reaction formulas of SiF₄ and CF₄, C₂F₆, C₃F₈, C₂F₄, and C₂HF are positive. From this, it is inferred that the reaction in which SiF₄ reacts with any of these fluorocarbons to form the silicon carbide on the right is unlikely to occur.

The reactivity of silicon tetrafluoride (SiF₄) with various hydrocarbons has also been studied. Tables 26 to 30 show the reaction Gibbs energies Gr based on the reaction formulas of SiF₄ with methane (CH₄), ethane (C₂H₆), propane (C₃H₈), ethylene (C₂H₄), and acetylene (C₂H₂) respectively.

TABLE 26

| | | | | | | | | | | |
|---|---|---|---|---|---|---|---|---|---|---|
| Reaction | 1 | CH4(g)+ | 1 | SiF4(g)→ | 1 | α-SiC(s)+ | 4 | HF(g)+ | 0 | F2(g) |

| [symbol] H(kJ/mol) | | −74.87 | −1614.94 | −62.8 | −271.1 | 0 |
|---|---|---|---|---|---|---|
| S(J/K · mol) | | 186.14 | 282.38 | 16.602 | 173.67 | 202.67 |
| Gf(kJ/mol) = | 25° C. | −130.34 | −1699.09 | −67.75 | −322.85 | −60.40 |
| H − TS | 1500° C. | −404.90 | −2115.60 | −92.24 | −579.02 | −359.33 |

| | | |
|---|---|---|
| Gr(kJ/mol) = | 25° C. | 470.3 |
| right − left | 1500° C. | 112.2 |

TABLE 27

| | | | | | | | | | | |
|---|---|---|---|---|---|---|---|---|---|---|
| Reaction | 1 | C2H6(g)+ | 1 | SiF4(g)→ | 1 | α-SiC(s)+ | 4 | HF(g)+ | 0 | F2(g) |

| [symbol] H(kJ/mol) | | −83.8 | −1614.94 | −62.8 | −271.1 | 0 |
|---|---|---|---|---|---|---|
| S(J/K · mol) | | 229.1 | 282.38 | 16.602 | 173.67 | 202.67 |
| Gf(kJ/mol) = | 25° C. | −152.07 | −1699.09 | −67.75 | −322.85 | −60.40 |
| H − TS | 1500° C. | −489.99 | −2115.60 | −92.24 | −579.02 | −359.33 |

| | | |
|---|---|---|
| Gr(kJ/mol) = | 25° C. | 492.0 |
| right − left | 1500° C. | 197.3 |

TABLE 28

| | | | | | | | | | | |
|---|---|---|---|---|---|---|---|---|---|---|
| Reaction | 1 | C3H8(g)+ | 3 | SiF4(g)→ | 3 | α-SiC(s)+ | 8 | HF(g)+ | 2 | F2(g) |

| [symbol] H(kJ/mol) | | −104.7 | −1614.94 | −62.8 | −271.1 | 0 |
|---|---|---|---|---|---|---|
| S(J/K · mol) | | 270.2 | 282.38 | 16.602 | 173.67 | 202.67 |
| Gf(kJ/mol) = | 25° C. | −185.22 | −1699.09 | −67.75 | −322.85 | −60.40 |
| H − TS | 1500° C. | −583.76 | −2115.60 | −92.24 | −579.02 | −359.33 |

| | | |
|---|---|---|
| Gr(kJ/mol) = | 25° C. | 791.9 |
| right − left | 1500° C. | 434.4 |

TABLE 29

| | | | | | | | | | | |
|---|---|---|---|---|---|---|---|---|---|---|
| Reaction | 1 | C2H4(g)+ | 2 | SiF4(g)→ | 2 | α-SiC(s)+ | 4 | HF(g)+ | 2 | F2(g) |

| [symbol] H(kJ/mol) | | −74.87 | −1614.94 | −62.8 | −271.1 | 0 |
|---|---|---|---|---|---|---|
| S(J/K · mol) | | 186.14 | 282.38 | 16.602 | 173.67 | 202.67 |
| Gf(kJ/mol) = | 25° C. | −130.34 | −1699.09 | −67.75 | −322.85 | −60.40 |
| H − TS | 1500° C. | −404.90 | −2115.60 | −92.24 | −579.02 | −359.33 |

| | | |
|---|---|---|
| Gr(kJ/mol) = | 25° C. | 990.4 |
| right − left | 1500° C. | 708.4 |

TABLE 30

| | | | | | | | | | | |
|---|---|---|---|---|---|---|---|---|---|---|
| Reaction | 1 | C2H2(g)+ | 2 | SiF4(g)→ | 2 | α-SiC(s)+ | 2 | HF(g)+ | 3 | F2(g) |

| [symbol] H(kJ/mol) | | −74.87 | −1614.94 | −62.8 | −271.1 | 0 |
|---|---|---|---|---|---|---|
| S(J/K · mol) | | 186.14 | 282.38 | 16.602 | 173.67 | 202.67 |
| Gf(kJ/mol) = | 25° C. | −130.34 | −1699.09 | −67.75 | −322.85 | −60.40 |
| H − TS | 1500° C. | −404.90 | −2115.60 | −92.24 | −579.02 | −359.33 |

| | | |
|---|---|---|
| Gr(kJ/mol) = | 25° C. | 1283.1 |
| right − left | 1500° C. | 1107.8 |

As shown in Tables 26 to 30, the reaction Gibbs energies Gr at 1500° C. based on the reaction formulas of SiF₄ and CH₄, C₂H₆, C₃H₈, C₂H₄, and C₂H₂ are all positive. From this, it is inferred that the reaction in which SiF₄ reacts with any of these hydrocarbons to form the silicon carbide on the right is unlikely to occur.

Next, the reactivity of disilicon hexafluoride (Si₂F₆) with various fluorocarbons is studied. Tables 31 to 35 show the reaction Gibbs energies Gr based on the reaction formulas of Si₂F₆ with tetrafluoromethane (CF₄), hexafluoroethane (C₂F₆), octafluoropropane (C₃F₈), tetrafluoroethylene (C₂F₄) and fluorinated acetylene (C₂HF) respectively.

TABLE 31

| | | | | | | | | | |
|---|---|---|---|---|---|---|---|---|---|
| Reaction | 2 | CF4(g)+ | 1 | Si2F6(g)→ | 2 | α-SiC(s)+ | 0 | 7 | F2(g) |

| [symbol] H(kJ/mol) | | −930 | −2383.29 | −62.8 | | 0 |
|---|---|---|---|---|---|---|
| S(J/K · mol) | | 261.3 | 390.983 | 16.602 | | 202.67 |
| Gf(kJ/mol) = | 25° C. | −1007.87 | −2499.80 | −67.75 | 0.00 | −60.40 |
| H − TS | 1500° C. | −1393.28 | −3076.50 | −92.24 | 0.00 | −359.33 |

| | | |
|---|---|---|
| Gr(kJ/mol) = | 25° C. | 1978.6 |
| right − left | 1500° C. | 1581.6 |

TABLE 32

| | | | | | | | | | |
|---|---|---|---|---|---|---|---|---|---|
| Reaction | 1 | C2F6(g)+ | 1 | Si2F6(g)→ | 2 | α-SiC(s)+ | 0 | 6 | F2(g) |

| [symbol] H(kJ/mol) | | −1343.9 | −2383.29 | −62.8 | | 0 |
|---|---|---|---|---|---|---|
| S(J/K · mol) | | 331.98 | 390.983 | 16.602 | | 202.67 |
| Gf(kJ/mol) = | 25° C. | −1442.83 | −2499.80 | −67.75 | 0.00 | −60.40 |
| H − TS | 1500° C. | −1932.50 | −3076.50 | −92.24 | 0.00 | −359.33 |

| | | |
|---|---|---|
| Gr(kJ/mol) = | 25° C. | 1722.4 |
| right − left | 1500° C. | 1334.3 |

TABLE 33

| | | | | | | | | | |
|---|---|---|---|---|---|---|---|---|---|
| Reaction | 2 | C3F8(g)+ | 3 | Si2F6(g)→ | 6 | α-SiC(s)+ | 0 | 17 | F2(g) |

| [symbol] H(kJ/mol) | | −1783.2 | −2383.29 | −62.8 | | 0 |
|---|---|---|---|---|---|---|
| S(J/K · mol) | | 0 | 390.983 | 16.602 | | 202.67 |
| Gf(kJ/mol) = | 25° C. | −1783.20 | −2499.80 | −67.75 | 0.00 | −60.40 |
| H − TS | 1500° C. | −1783.20 | −3076.50 | −92.24 | 0.00 | −359.33 |

| | | |
|---|---|---|
| Gr(kJ/mol) = | 25° C. | 1605.4 |
| right − left | 1500° C. | 1022.3 |

TABLE 34

| | | | | | | | | | |
|---|---|---|---|---|---|---|---|---|---|
| Reaction | 1 | C2F4(g)+ | 1 | Si2F6(g)→ | 2 | α-SiC(s)+ | 0 | 5 | F2(g) |

| [symbol] H(kJ/mol) | | −12.43 | −2383.29 | −62.8 | | 0 |
|---|---|---|---|---|---|---|
| S(J/K · mol) | | 343.31 | 390.983 | 16.602 | | 202.67 |
| Gf(kJ/mol) = | 25° C. | −114.74 | −2499.80 | −67.75 | 0.00 | −60.40 |
| H − TS | 1500° C. | −621.12 | −3076.50 | −92.24 | 0.00 | −359.33 |

| | | |
|---|---|---|
| Gr(kJ/mol) = | 25° C. | 1088.5 |
| right − left | 1500° C. | 858.2 |

TABLE 35

| | | | | | | | | | | |
|---|---|---|---|---|---|---|---|---|---|---|
| Reaction | 1 | C2HF(g)+ | 1 | Si2F6(g)→ | 2 | α-SiC(s)+ | 1 | HF(g)+ | 3 | F2(g) |

| [symbol] H(kJ/mol) | | 125.52 | −2383.29 | −62.8 | −271.1 | 0 |
|---|---|---|---|---|---|---|
| S(J/K · mol) | | 231.5 | 390.983 | 16.602 | 173.67 | 202.67 |
| Gf(kJ/mol) = | 25° C. | 56.53 | −2499.80 | −67.75 | −322.85 | −60.40 |
| H − TS | 1500° C. | −284.93 | −3076.50 | −92.24 | −579.02 | −359.33 |

| | | |
|---|---|---|
| Gr(kJ/mol) = | 25° C. | 901.9 |
| right − left | 1500° C. | 760.0 |

As shown in Tables 31 to 35, the reaction Gibbs energies Gr at 1,500° C. based on the reaction formulas of Si₂F₆ with CF₄, C₂F₆, C₃F₈, C₂F₄, and C₂HF are all positive. From this, it is inferred that the reaction in which SiF₄ reacts with any of these hydrocarbons to form the silicon carbide on the right is unlikely to occur.

The reactivity of Si₂F₆ with various hydrocarbons is also studied. Tables 36 to 40 show the reaction Gibbs energies Gr based on the reaction formulas of Si₂F₆ with methane (CH₄), ethane (C₂H₆), propane (C₃H₈), ethylene (C₂H₄), and acetylene (C₂H₂), respectively.

TABLE 36

| | | | | | | | | | | |
|---|---|---|---|---|---|---|---|---|---|---|
| Reaction | 2 | CH4(g)+ | 1 | Si2F6(g)→ | 2 | α-SiC(s)+ | 8 | HF(g)+ | 1 | H2(g) |

| [symbol] H(kJ/mol) | | −74.87 | −2383.29 | −62.8 | −271.1 | 0 |
|---|---|---|---|---|---|---|
| S(J/K · mol) | | 186.14 | 390.983 | 16.602 | 173.67 | 130.575 |
| Gf(kJ/mol) = | 25° C. | −130.34 | −2499.80 | −67.75 | −322.85 | −38.91 |
| H − TS | 1500° C. | −404.90 | −3076.50 | −92.24 | −579.02 | −231.51 |

| | | |
|---|---|---|
| Gr(kJ/mol) = | 25° C. | 1.6 |
| right − left | 1500° C. | −580.9 |

TABLE 37

| | | | | | | | | | |
|---|---|---|---|---|---|---|---|---|---|
| Reaction | 1 | C2H6(g)+ | 1 | Si2F6(g)→ | 1 | α-SiC(s)+ | 6 | HF(g)+ | 0 |

| | | | | | | |
|---|---|---|---|---|---|---|
| [symbol] H(kJ/mol) | | −83.8 | −2383.29 | −62.8 | −271.1 | |
| S(J/K · mol) | | 229.1 | 390.983 | 16.602 | 173.67 | |
| Gf(kJ/mol) = | 25° C. | −152.07 | −2499.80 | −67.75 | −322.85 | 0.00 |
| H − TS | 1500° C. | −489.99 | −3076.50 | −92.24 | −579.02 | 0.00 |

| | | |
|---|---|---|
| Gr(kJ/mol) = | 25° C. | 647.0 |
| right − left | 1500° C. | 0.2 |

TABLE 38

| | | | | | | | | | | |
|---|---|---|---|---|---|---|---|---|---|---|
| Reaction | 2 | C3H8(g)+ | 3 | Si2F6(g)→ | 6 | α-SiC(s)+ | 16 | HF(g)+ | 1 | F2(g) |

| [symbol] H(kJ/mol) | | −104.7 | −2383.29 | −62.8 | −271.1 | 0 |
|---|---|---|---|---|---|---|
| S(J/K · mol) | | 270.2 | 390.983 | 16.602 | 173.67 | 202.67 |
| Gf(kJ/mol) = | 25° C. | −185.22 | −2499.80 | −67.75 | −322.85 | −60.40 |
| H − TS | 1500° C. | −583.76 | −3076.50 | −92.24 | −579.02 | −359.33 |

| | | |
|---|---|---|
| Gr(kJ/mol) = | 25° C. | 372.9 |
| right − left | 1500° C. | 36.7 |

TABLE 39

| | | | | | | | | | | |
|---|---|---|---|---|---|---|---|---|---|---|
| Reaction | 2 | C3H8(g)+ | 3 | Si2F6(g)→ | 6 | α-SiC(s)+ | 16 | HF(g)+ | 1 | F2(g) |

| [symbol] H(kJ/mol) | | −104.7 | −2383.29 | −62.8 | −271.1 | 0 |
|---|---|---|---|---|---|---|
| S(J/K · mol) | | 270.2 | 390.983 | 16.602 | 173.67 | 202.67 |
| Gf(kJ/mol) = | 25° C. | −185.22 | −2499.80 | −67.75 | −322.85 | −60.40 |
| H − TS | 1500° C. | −583.76 | −3076.50 | −92.24 | −579.02 | −359.33 |

| | | |
|---|---|---|
| Gr(kJ/mol) = | 25° C. | 372.9 |
| right − left | 1500° C. | 36.7 |

TABLE 40

| | | | | | | | | | | |
|---|---|---|---|---|---|---|---|---|---|---|
| Reaction | 1 | C2H2(g)+ | 1 | Si2F6(g)→ | 2 | α-SiC(s)+ | 2 | HF(g)+ | 2 | F2(g) |

| [symbol] H(kJ/mol) | | −74.87 | −2383.29 | −62.8 | −271.1 | 0 |
|---|---|---|---|---|---|---|
| S(J/K · mol) | | 186.14 | 390.983 | 16.602 | 173.67 | 202.67 |
| Gf(kJ/mol) = | 25° C. | −130.34 | −2499.80 | −67.75 | −322.85 | −60.40 |
| H − TS | 1500° C. | −404.90 | −3076.50 | −92.24 | −579.02 | −359.33 |

| | | |
|---|---|---|
| Gr(kJ/mol) = | 25° C. | 864.1 |
| right − left | 1500° C. | 710.1 |

As shown in Tables 36 to 40, if CH₄ is excluded, the reaction Gibbs energies Gr at 1,500° C. based on the reaction formulas of Si₂F₆ with C₂H₆, C₃H₈, C₂H₄ and C₂H₂ are all positive. From this, it is believed that the reaction in which Si₂F₆ reacts with any of these hydrocarbons to generate the silicon carbide on the right is unlikely to occur. In the case of CH₄, since the reaction Gibbs energy with Si₂F₆ at 1,500° C. is negative, the reaction to generate silicon carbide on the right side of the reaction formula may proceed. Therefore, it is necessary to conduct research when using a combination of Si₂F₆ and CH₄ as the material gas.

In this way, when studying chemical reactivity based on the reaction Gibbs energy, it is clarified that the reaction Gibbs energy of silicon tetrafluoride (SiF₄) and silicon hexafluoride (Si₂F₆) with various fluorocarbons or hydrocarbons is approximately positive at a temperature of about 1,500° C. for forming the epitaxial growth layer 13, and the reaction to form silicon carbide does not proceed spontaneously. Therefore, in the furnace chamber 211 of the reaction furnace 210, even if SiF₄ and Si₂F₆ and various fluorocarbons or hydrocarbons are used as material gases in an atmosphere of about 1,500° C., the reaction to form silicon carbide will not occur. It is believed that the single crystal gradually grows epitaxially on the Si plane of the SiC monocrystalline substrate 11 at the interface adjacent the graphene layer 12.

Returning to step S23 in FIG. 11, when silicon fluoride and hydrocarbons are introduced into the furnace chamber 211 as material gases for forming the SiC epitaxial growth layer 13, in the reaction furnace 210 called a batch type vertical tubular furnace, since the uniform heating length in the furnace chamber 211 is relatively long, it is contemplated to thermally decompose silicon tetrafluoride (SiF₄) gradually in the furnace chamber 211. For the silicon fluoride, it may use the Si₂F₆ monomer or a mixed gas of SiF₄ and Si₂F₆ with an adjusted mixing ratio. For hydrocarbons, methane (CH₄), ethane (C₂H₆), propane (C₃H₈), ethylene (C₂H₄), acetylene (C₂H₂), etc. can be used as well.

Although a combination of silicon fluoride and hydrocarbon has been shown as the material gas, a combination of silicon fluoride and fluorocarbon may be used instead of or together with the combination of silicon fluoride and hydrocarbon. Tetrafluoromethane (CF₄), hexafluoroethane (C₂F₆), octafluoropropane (C₃F₈), tetrafluoroethylene (C₂F₄), fluoroacetylene (C₂HF), etc. can also be used for fluorocarbons. In addition, silicon fluoride is not limited to silicon tetrafluoride (SiF₄), and other silicon fluorides such as disilicon hexafluoride (Si₂F₆) can also be used.

In addition, as mentioned above, high-order silicon fluoride gases, such as trisilicon octafluoride (Si₃F₈) or those having higher order have the property that the higher the order of the compound, the lower the thermal decomposition temperature, and the easier it is to release Si atoms and fluorine atoms. When used for SiC epitaxial growth, Si precursor gas (silicon fluoride gas) and carbon precursor gas (carbon fluoride gas) are used together to adjust the composition ratio of the grown SiC single crystal to Si:C=1:1 (Stoichiometric composition ratio=stoichiometry). However, high-order silicon fluoride gases, such as trisilicon octafluoride (Si₃F₈) gas or those having higher order are easily decomposed at relatively low temperatures. In contrast, it is necessary to balance the supply amount of carbon from the fluorocarbon gas, and it is necessary for silicon carbon gases to use even higher order compounds. In this case, the decomposition process of each gas in the furnace becomes easy to proceed, and it becomes difficult to optimize the batch-to-batch and in-plane uniformity of the stoichiometry. Under such circumstance, if the growth temperature is lowered, then the optimal adjustment will become easier, but on the contrary, the crystal quality of SiC is likely to decrease due to polymorphous blending, which is equal to an increase in inclusions, etc. For this reason, in the embodiment, in view of practicality, it is limited to use low-order silicon fluoride gases not higher than disilicon hexafluoride gas only.

In addition, as mentioned above, although chlorine gas (Cl₂) has properties close to silicon tetrafluoride (SiF₄), when used for SiC epitaxial growth, Cl₂ is a compound that does not contain Si or C and cannot be used as a stacking gas. Although it is also contemplated to be used as an additive gas, it is considered that there is almost no advantage in adding Cl₂ because stacking gases such as SiF₄ or C₂F₆ are less likely to etch carbon than Cl₂ and are easy to preserve.

After the SiC epitaxial growth layer 13 grown on the graphene layer 12 reaches a required thickness and the second composite 82, in which the SiC epitaxial growth layer 13 is stacked on the SiC monocrystalline substrate 11 with the graphene layer 12 interposed therebetween, is formed in step S24, the supply of the material gas is stopped immediately in step S25. Further, the temperature of the furnace chamber 211 is lowered in step S26, the supply of Ar gas is stopped in step S27, and then the second composite 82 is taken out from the furnace chamber 211. In addition, the Ar gas serving as the carrier gas may be switched to hydrogen gas in the middle of forming the SiC epitaxial growth layer 13. This can almost completely suppress unnecessary deposits on the inner wall of the furnace chamber 211 and the like, so that the maintenance cycle and the life of the furnace fixtures can be extended.

### (Semiconductor Manufacturing Apparatus According to Modified Example)

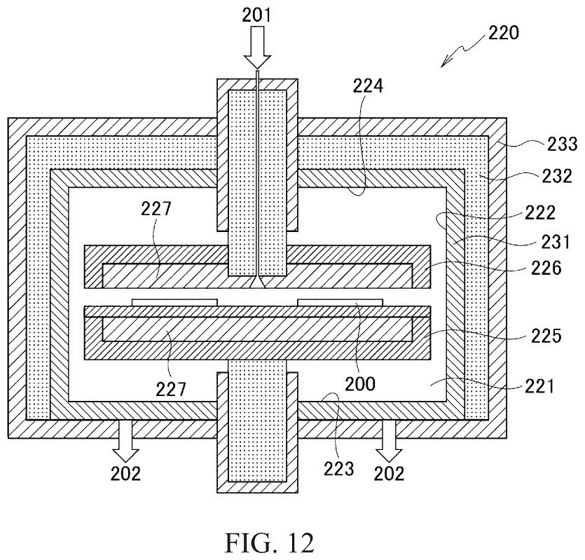

FIG. 12 is a diagram showing a reaction furnace 220 according to a modified example. In the series of steps of forming the first composite 81 shown in FIGS. 7 and 9 and the steps of forming the second composite shown in FIG. 11, although the reaction furnace 210, also known as a batch type vertical tubular furnace, is used, the reaction furnace 220 of the modified example shown in FIG. 12 can also be used as the semiconductor manufacturing apparatus of the modified example.

In the furnace chamber 221 of the reaction furnace 220 of the modified example, a workbench 225 on which a plurality of film-forming substrates 200 can be placed and a mask 226 facing the workbench 225 with a predetermined gap therebetween are supported by pillars extending from a bottom plate 223 and a top plate 224 of the furnace chamber 221. A gas supply hole for supplying the gas 201 is provided substantially in the center of the bottom surface of the mask 226. In addition, the bottom plate 223 of the furnace chamber 221 is provided with an exhaust port for discharging exhaust gas 202 from the furnace chamber 221. The workbench 225 and the mask 226 each have a resistance heating heater 227. The surfaces of the workbench 225 and the mask 226 and the furnace wall 222 are formed by the SiC base 231 and are further surrounded by a heat insulating material 232 and a water cooling chamber 233. The surfaces of the workbench 225 and the mask 226 are also covered by the SiC base. The reaction furnace 220 of the modified example is also called a semi-batch reactor.

In the reaction furnace 220 of the modified example, like the reaction furnace 210 of the embodiment, the first composite 81 can also be formed through a series of steps shown in FIGS. 7 and 9. In addition, the second composite 82 can be formed through a series of steps shown in FIG. 11. However, compared with the reaction furnace 210 called a batch type vertical tubular furnace according to the embodiment, the reaction furnace 220 called a semi-batch reactor according to the modified example has a shorter uniform heating length. Therefore, silicon tetrafluoride (SiF₄) monomers can be used for the silicon fluoride gas without considering the loss due to decomposition of silicon tetrafluoride (SiF₄).

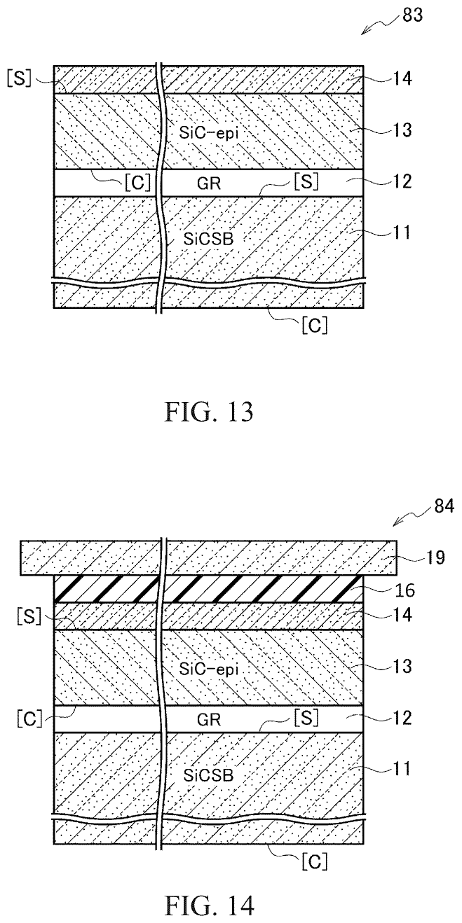

As shown in FIG. 13, the stress layer 14 is formed on the SiC epitaxial growth layer 13 of the second composite 82 to form the third composite 83. The stress layer 14 generates stress between the graphene layer 12 and the SiC epitaxial growth layer 13, making it easier to peel the graphene layer 12 from the SiC epitaxial growth layer 13.

The stress layer 14 of the embodiment is composed of a carbon film. The carbon film is composed of polycrystalline diamond film or diamond-like carbon film. When the carbon film is a polycrystalline diamond film, it can be obtained by a microwave chemical vapor deposition (CVD) apparatus, etc., and when it is a diamond-like carbon film, it can be obtained by a radio frequency (RF) plasma chemical vapor deposition (CVD) apparatus etc. When forming the carbon film, the required film adhesion can be obtained by forming the film while applying a negative potential to the film-forming substrate side for applying ion impact in the initial stage of film formation.

As shown in FIG. 14, an adhesive layer 16 is formed on the stress layer 14 of the third composite 83. The coating surface of the adhesive layer 16 is overlapped and attached to one side of a graphite substrate 19, which is a temporary substrate having an outline size slightly greater than the SiC monocrystalline substrate 11, to form a fourth composite 84.

In the embodiment, a carbon adhesive is used for the adhesive layer 16. The carbon adhesive is an adhesive that contains phenolic resin, a thermosetting resin, as the main component and is blended with solid carbon components, etc., so it can maintain bonding strength through self-carbonization even at high temperatures.

The graphite substrate 19 may have a glassy carbon film on its surface. Since the adhesive force between the glassy carbon film and the carbon adhesive is strong, the SiC epitaxial growth layer 13 can be easily peeled off from the graphene layer 12 and the SiC monocrystalline substrate 11, thereby improving the yield.

The graphite substrate 19 is a temporary substrate with a slightly larger outline size. For example, if the SiC monocrystalline substrate 11 has a diameter of about 10 cm, then a graphite substrate 19 with a diameter of about 11 cm that is about 10 mm larger is used. For example, if the SiC monocrystalline substrate 11 is about 15 cm in diameter, then a graphite substrate 19 with an outline size of about 16 cm in diameter is used. When the temporary substrate (the graphite substrate 19) that is larger than the SiC monocrystalline substrate 11 in size is inserted and neatly arranged in the wafer boat tank of the batch-type vertical CVD furnace, it has the advantage of keeping the boat support mark outside the substrate active area.

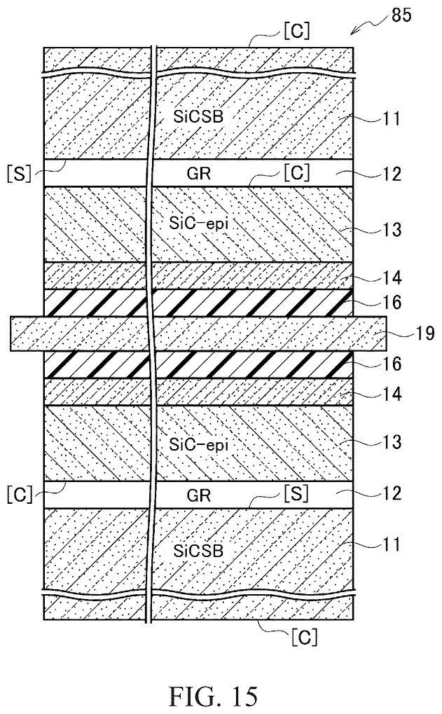

As shown in FIG. 15, the stress layer 14 of the third composite 83 may be attached to both surfaces of the graphite substrate 19 of the temporary substrate via the adhesive layer 16 to form a fifth composite 85. In this case, the adhesive layer 16 is formed on the stress layer 14 of each third composite 83, and is attached to both sides of the graphite substrate 19 of the temporary substrate whose outline size is slightly greater than the SiC monocrystalline substrate 11. Regarding the fifth composite 85, an adhesive containing a thermosetting resin such as a carbon adhesive as a main component and mixed with a solid carbon component is also used for the adhesive layer 16, and the adhesive layer 16 is heated in a vacuum annealing furnace or the like for drying and curing. Regarding the fifth composite 85, the graphite substrate 19 of the temporary substrate may have a glassy carbon film on the surface, which is the same as the fourth composite 84 shown in FIG. 14. Hereinafter, the manufacturing method of the semiconductor substrate will be described using the fifth composite 85, in which the third composite 83 is attached to both sides of the graphite substrate 19 of the temporary substrate. However, the manufacturing method can also be applied to the fourth composite 84, in which the third composite 83 is attached to only one side of the graphite substrate 19 of the temporary substrate.

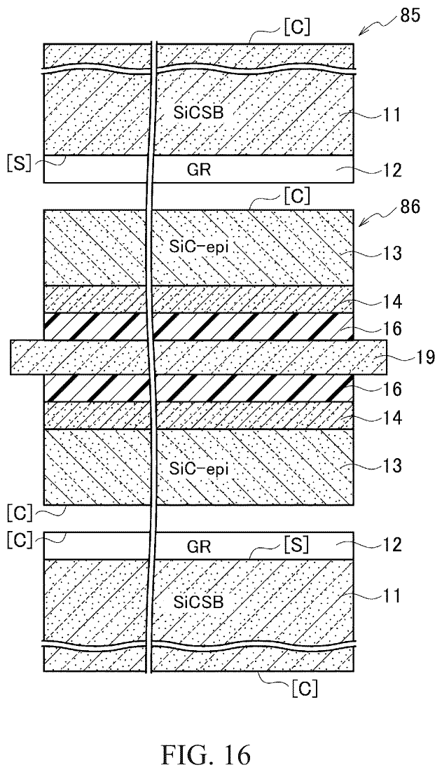

As shown in FIG. 16, after the fifth composite 85 in FIG. 15 is cured, the SiC epitaxial growth layer 13 is physically peeled off and separated from the graphene layer 12 using an adhesive peeling tape, a debonding apparatus, or the like on both sides of the fifth composite 85. After removing the SiC monocrystalline substrate 11 and the graphene layer 12 separated from the fifth composite 85, a sixth composite 86 is formed.

The graphene layer 12 is removed from the laminate of the SiC monocrystalline substrate 11 and the graphene layer 12 removed from the fifth composite 85 by etching or polishing. In the process of etching the graphene layer 12, plasma ashing using oxygen plasma can be applied, for example. Since the surface is oxidized in the Si plane of the SiC monocrystalline substrate 11 during the etching of the graphene layer 12 by oxygen plasma, wet etching using hydrogen fluoride (HF) is performed. In addition, in the step of polishing the graphene layer 12, the graphene layer 12 is removed by, for example, chemical mechanical polishing (CMP). Here, in the Si plane of the SiC monocrystalline substrate 11, the average roughness Ra of the surface in the wet etching process is, for example, about 1 nm or less. As a result, the SiC monocrystalline substrate 11 can be reused.

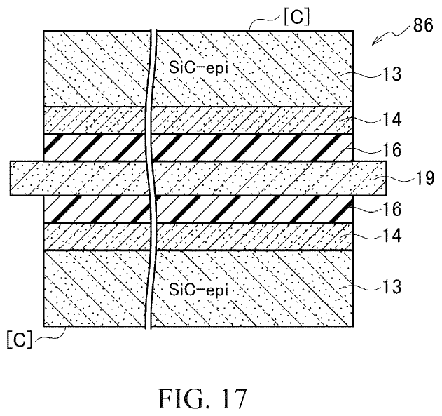

FIG. 17 shows the sixth composite 86. The sixth composite 86 is heated in a vacuum or an inert gas atmosphere in an annealing furnace, so that the adhesive layer 16 is carbonized. The carbon adhesive constituting the adhesive layer 16 can obtain appropriate adhesive strength after the carbonization treatment.

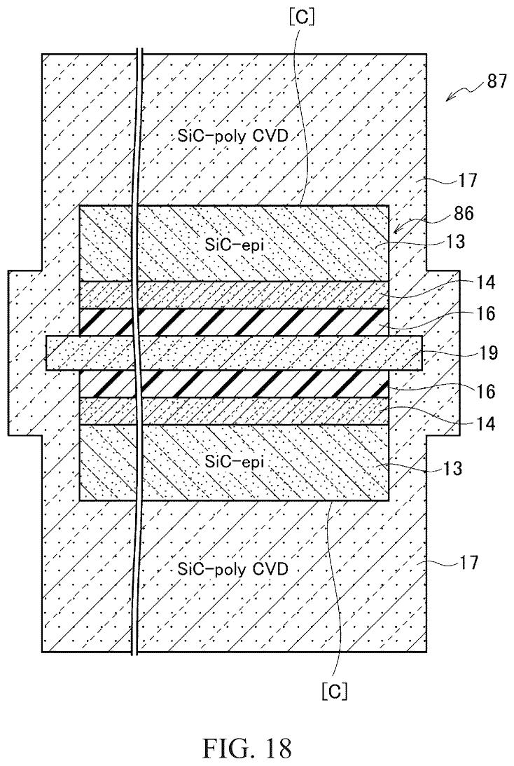

As shown in FIG. 18, a SiC polycrystalline growth layer (SiC-poly) 17 is formed on the C plane of the SiC epitaxial growth layer 13 of the sixth composite 86. The SiC polycrystalline growth layer 17 can be formed by CVD technology, for example. The SiC polycrystalline growth layer 17 has a 3C (cubic crystal) structure and is also called α-SiC. The SiC polycrystalline growth layer 17 is formed on the C plane of the SiC epitaxial growth layer 13 to form a matrix layer of the device wafer structure. Since the C plane of the SiC epitaxial growth layer 13 becomes the back surface of the device wafer structure, the requirement for surface flatness is not high. Therefore, the SiC polycrystalline growth layer 17 can be formed by a simple polishing process.

The SiC polycrystalline growth layer 17 is deposited and stacked to a thickness that can obtain mechanical strength required as a substrate for a SiC-based semiconductor element, thereby forming a seventh composite 87. The film thickness of the SiC polycrystalline growth layer 17 is expected to be between about 150 μm and about 500 μm. The plate thickness of the completed SiC composite substrate (the SiC polycrystalline growth layer 17+the SiC epitaxial growth layer 13) is adjusted to between about 150 μm and about 500 μm as needed. By thinning the film thickness of the SiC polycrystalline growth layer 17, the thermal conductivity is improved. In addition, it is desirable that the deposition temperature of the SiC polycrystalline growth layer 17 is in the range of about 1300° C. to about 1600° C.

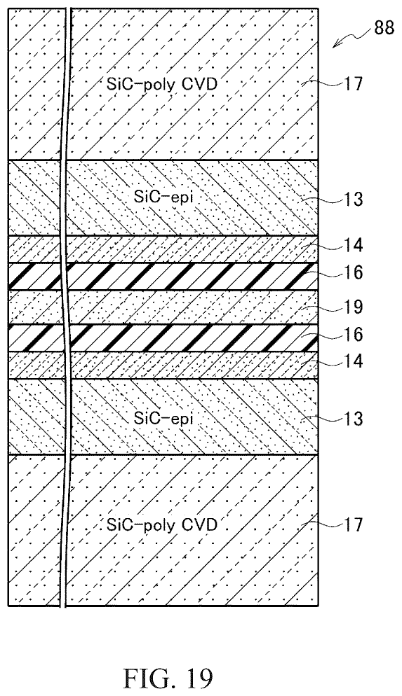

As shown in FIG. 19, the SiC polycrystalline growth layer 17 formed on the outer periphery of the seventh composite 87 and the unnecessary portions of the graphite substrate 19 of the temporary substrate are ground and removed using a peripheral grinding device to form an eighth composite 88 in which the SiC epitaxial growth layer 13, the stress layer 14, the adhesive layer 16 and the graphite substrate 19 are exposed. In the eighth composite 88, by exposing the graphite substrate 19 and the like, the graphite substrate 19 and the like can be removed by burning. In FIG. 19, the outer periphery of the eighth composite 88 has a unique outline in the direction of each stacked layer.

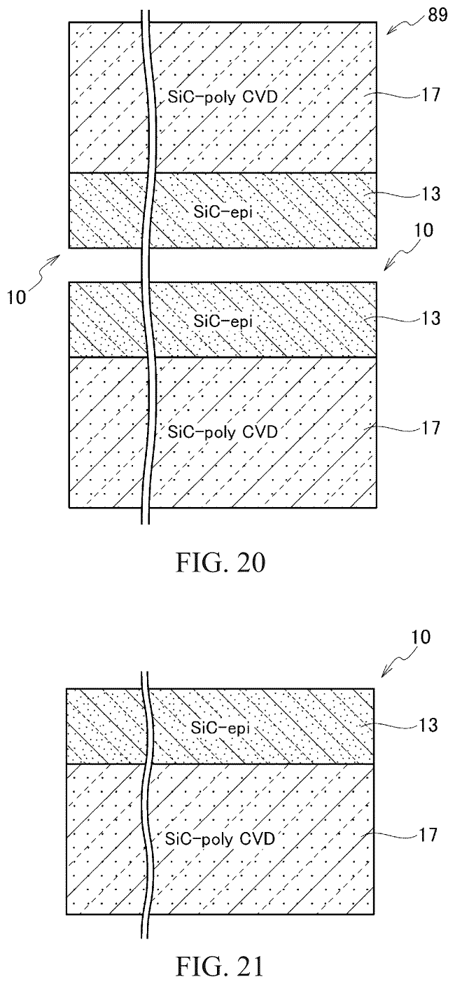

As shown in FIG. 20, the eighth composite 88 is heated in the air or oxygen atmosphere in a thermal annealing furnace, and the graphite substrate 19 and the carbonized adhesive layer 16 are removed by oxidative combustion. The stress layer 14 composed of the carbon film is also removed by oxidation and combustion, forming a ninth composite 89. The ninth composite 89 is composed of two blocks of SiC composite substrate 10 including the SiC epitaxial growth layer 13 and the SiC polycrystalline growth layer 17 disposed on the C plane of the SiC epitaxial growth layer 13.

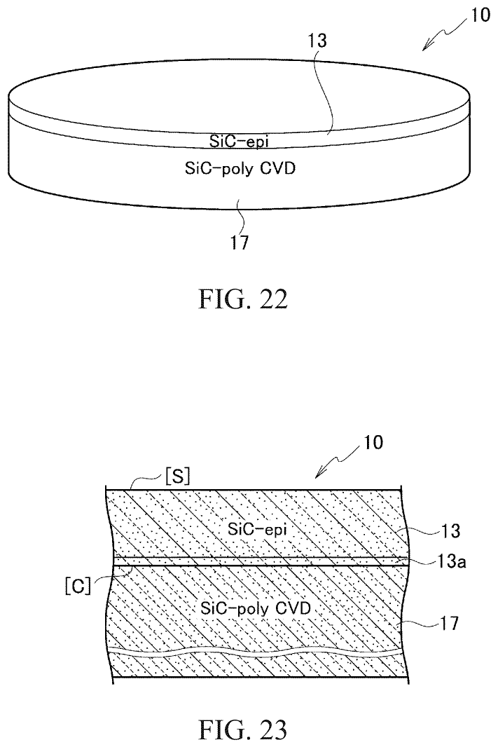

FIG. 21 shows a cross-sectional view of the SiC composite substrate 10. FIG. 22 shows a perspective view of the SiC composite substrate 10. In the SiC composite substrate 10, the surface of the SiC epitaxial growth layer 13 is the Si plane of α-SiC with the [0001] orientation of 4H—SiC, and the C plane is the plane with the [000-1] orientation of 4H—SiC. The thickness of the SiC polycrystalline growth layer 17 is, for example, between about 150 μm and about 500 μm, and the thickness of the SiC epitaxial growth layer 13 is, for example, between about 4 μm and about 100 μm.

In addition, as shown in FIG. 23, in the SiC epitaxial growth layer 13, a highly doped layer 13a may be formed toward the C plane of the SiC epitaxial growth layer 13 in contact with the SiC polycrystalline growth layer 17. The highly doped layer 13a can suppress the expansion of the depletion layer that expands in the SiC epitaxial growth layer 13, and can easily form an ohmic contact with the SiC polycrystalline growth layer 17 formed on the C plane of the SiC epitaxial growth layer 13.

The highly doped layer 13a can be formed using, for example, high-dose ion implantation technology. For example, in the case of an n-type semiconductor, phosphorus (P) ions are implanted at a high dose to form the highly doped layer 13a. When formed by P ion implantation, although there is an influence on the crystallinity of the C plane of the SiC epitaxial growth layer 13 into which P ions are implanted, the Si plane that becomes the device plane is already formed, and the crystallinity of the Si plane is preserved.

When forming the SiC epitaxial growth layer (SiC-epi) 13 shown in FIG. 10, the highly doped layer 13a may also be formed by forming an epitaxial growth layer doped with high concentration nitrogen (N) in the initial stage. In the epitaxial growth layer doped with high concentration nitrogen (N), although there is an influence on the crystallinity due to lattice constant mismatch, the process is relatively easy because it is formed by self-doping in the initial stage of epitaxial growth.

### (Semiconductor Manufacturing Method According to Modified Example)

In the embodiment, the stress layer 14 is composed of the carbon film such as the polycrystalline diamond film or the diamond-like carbon film. However, in a modified example, a silicon nitride film is used as a stress layer 15 of the modified example.

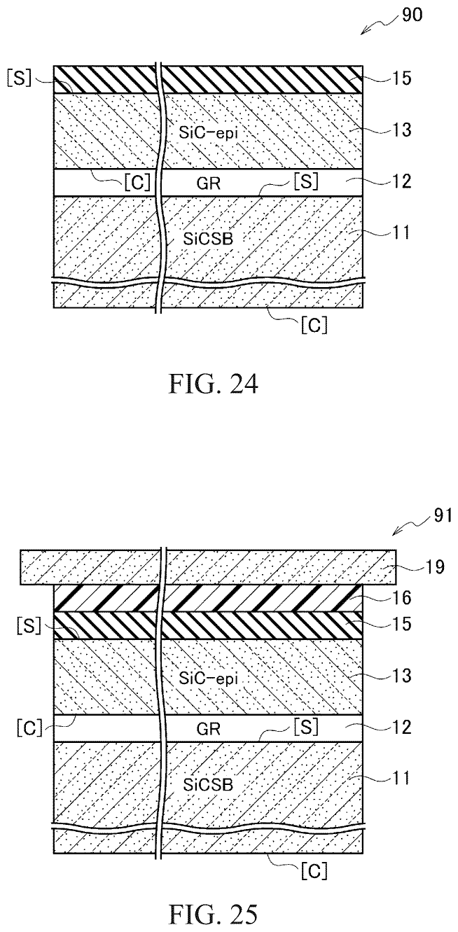

As shown in FIG. 24, the stress layer 15 of the modified example is laminated on the SiC epitaxial growth layer 13 of the second composite 82 to form a tenth composite 90. The stress layer 15 of the modified example also generates stress between the graphene layer 12 and the SiC epitaxial growth layer 13, making it easier to peel off the graphene layer 12 from the SiC epitaxial growth layer 13.

As shown in FIG. 25, an adhesive layer 16 is formed on the stress layer 15 of the modified example of the tenth composite 90, and the coated surface of the adhesive layer 16 is overlapped with and attached to one side of the graphite substrate 19 of the temporary substrate to form a eleventh composite 91. The eleventh composite 91 is heated in a vacuum annealing furnace or the like to dry and cure the adhesive layer 16.

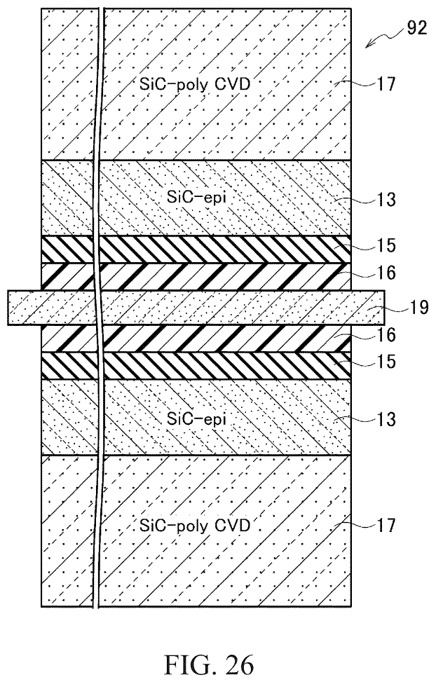

As shown in FIG. 26, the stress layer 15 of the modified example of the tenth composite 90 may also be affixed to both surfaces of the graphite substrate 19 of the temporary substrate via the adhesive layer 16 to form a twelfth composite 92. The twelfth composite 92 is heated in a vacuum annealing furnace or the like to dry and cure the adhesive layer 16.

Regardless of the case where the tenth composite 90 is bonded to one side of the graphite substrate 19 of the temporary substrate to form the eleventh composite 91, or the case where the tenth composites 90 are bonded to both sides of the graphite substrate 19 respectively to form the twelfth composite 92, the following is the same as in the embodiment. That is, the carbon adhesive is used for the adhesive layer 16, the graphite substrate 19 can have a glassy carbon film on the surface, and the outline size of the graphite substrate 19 of the temporary substrate is greater than the SiC monocrystalline substrate 11, so when the graphite substrate 19 is inserted and neatly arranged in the wafer boat tank of the batch-type vertical CVD furnace, there is the advantage of keeping the boat support mark outside the substrate active area. In the following description, the twelfth composite 92 in which the tenth composite 90 is bonded to both sides of the graphite substrate 19 is used. However, same goes for the eleventh composite 91 in which the tenth composite 90 is bonded to only one side of the graphite substrate 19.

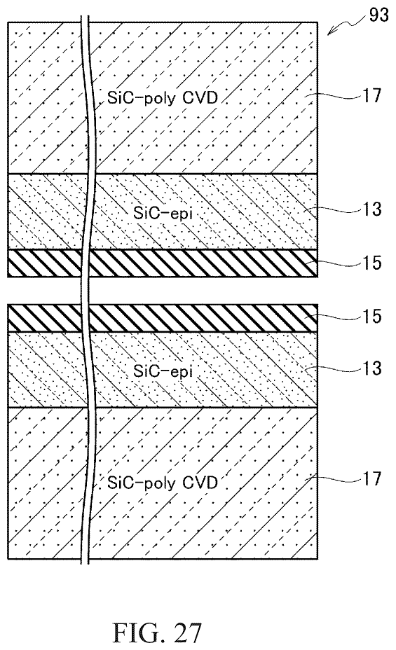

The thirteenth composite 93 shown in FIG. 27 is formed by subjecting the twelfth composite 92 to the same process as the embodiment shown in FIGS. 16 to 19. Specifically, the SiC epitaxial growth layer 13 is physically peeled off and divided from the interface of the graphene layer 12 to remove the SiC monocrystalline substrate 11 and the graphene layer 12, and the remaining composite is heated and the adhesive layer 16 is carbonized. After that, the SiC polycrystalline growth layer 17 is formed on the C plane of the SiC epitaxial growth layer 13. In addition, the SiC polycrystalline growth layer 17 formed on the periphery and the useless portion of the graphite substrate 19 of the temporary substrate are ground and removed by a peripheral grinding device, and then heated in an atmosphere or an oxygen atmosphere in a thermal annealing furnace, and the graphite substrate 19 and the carbonized adhesive layer 16 is oxidized, burned and removed. Since the stress layer 15 of the modified example is made of silicon nitride, unlike the stress layer 14 made of the carbon film according to the embodiment, the graphite substrate 19 and the carbonized adhesive layer 16 remain after being removed by oxidative combustion.

The stress layer 15 of the modified example made of silicon nitride in the thirteenth composite 93 is removed by an appropriate method such as etching and grinding. For etching, dry etching using fluorocarbon-based gas plasma or wet etching using hot phosphoric acid can be used. After the stress layer 15 is removed, like the ninth composite 89 of the embodiment shown in FIG. 20, two blocks of the SiC composite substrate 10 can be obtained. The SiC composite substrate 10 includes the SiC epitaxial growth layer 13 and the SiC polycrystalline growth layer 17 arranged on the C plane of the SiC epitaxial growth layer 13.

### (Semiconductor Substrate)

The semiconductor substrate of the embodiment is shown as the third composite 83 in FIG. 13. The graphene layer 12 is disposed on the Si plane of the SiC monocrystalline substrate 11, and the SiC epitaxial growth layer 13 is disposed on the graphene layer 12. Further, the stress layer 14 is arranged on the SiC epitaxial growth layer 13. The stress layer may be composed of the carbon film such as the polycrystalline diamond film or the diamond-like carbon film, or may be formed of a silicon nitride film.

In the semiconductor substrate of this embodiment, the SiC epitaxial growth layer 13 is formed in an atmosphere containing fluorine such as silicon fluoride or carbon fluoride, and the SiC epitaxial growth layer 13 contains fluorine. In the SiC epitaxial growth of the previous technology, atmospheric nitrogen mainly enters the C site (C is replaced with N) of the SiC crystal structure, usually at an impurity concentration of 10¹⁵ to 10¹⁸ levels per cubic centimeter. However, in the semiconductor substrate of the embodiment, since fluorine has a higher reactivity with Si than nitrogen, it becomes a state in which part of the nitrogen impurity concentration is replaced by fluorine. The fluorine concentration is about 10¹⁵ levels per cubic centimeter or less. From the semiconductor substrate of this embodiment, the SiC composite substrate 10 shown in FIG. 21 can be obtained according to the manufacturing method of the semiconductor substrate of the embodiment.

Specifically, as shown in FIG. 14, the stress layer 14 of the third composite 83 can be attached to one side of the graphite substrate 19 of the temporary substrate through the adhesive layer 16, or as shown in FIG. 15, the stress layer 14 of the third composite 83 is attached to both sides of the graphite substrate 19 via the adhesive layer 16 to form the fifth composite 85. The graphite substrate 19 may have an outline size greater than that of the SiC monocrystalline substrate 11, and may also have a glassy carbon film on its surface. The adhesive layer 16 may also be composed of carbon adhesive.

Taking the fifth composite 85 as an example, after the adhesive layer 16 is cured, as shown in FIG. 16, the SiC epitaxial growth layer 13 is physically peeled off and divided from the interface of the graphene layer 12, and the SiC monocrystalline substrate 11 and the graphene layer 12 are removed to form the sixth composite 86. Then, as shown in FIG. 18, the SiC polycrystalline growth layer 17 is formed on the C plane of the SiC epitaxial growth layer 13 of the sixth composite 86, and after polishing the outer periphery and removing the graphite substrate 19 of the temporary substrate, the adhesive layer 16 and the stress layer 14, the SiC composite substrate 10 can be obtained in either the upper or lower block, like the ninth composite 89 as shown in FIG. 20.

### (Semiconductor Elements)

The SiC composite substrate 10 produced by the manufacturing method of the semiconductor substrate according to the embodiment or the SiC composite substrate 10 produced from the semiconductor substrate of the embodiment can be used for the production of various SiC-based semiconductor elements, for example. Hereinafter, as the examples thereof, SiC-SBD, SiC trench gate type TMOSFET, and SiC planar gate type MOSFET will be described.

### (SiC-SBD)

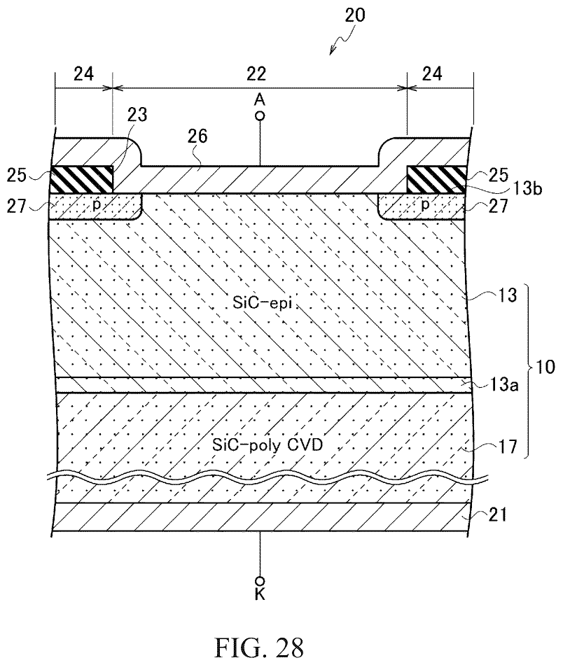

As a semiconductor element produced using the SiC composite substrate, a SiC-SBD 20 has the SiC composite substrate 10 including the SiC polycrystalline growth layer (SiC-poly) 17 and the SiC epitaxial growth layer (SiC-epi) 13, as shown in FIG. 28. In addition, the highly doped layer 13a may be interposed between the SiC polycrystalline growth layer 17 and the SiC epitaxial growth layer 13. Here, the highly doped layer 13a can suppress the expansion of the depletion layer that expands in the SiC epitaxial growth layer 13 and easily forms ohmic contact with the SiC polycrystalline growth layer 17 formed on the C plane of the SiC epitaxial growth layer 13. The SiC epitaxial growth layer 13 is a drift layer, the highly doped layer 13a is a buffer layer, and the SiC polycrystalline growth layer 17 is a matrix layer.

The SiC polycrystalline growth layer 17 is doped to n+ type (the impurity density is, for example, between about 1×10¹⁸ cm⁻³ and about 1×10²¹ cm⁻³), and the SiC epitaxial growth layer 13 is doped to n⁻-type (the impurity density is, for example, between about 5×10¹⁴ cm⁻³ and about 5×10¹⁶ cm⁻³). The highly doped layer 13a is doped to a concentration higher than that of the SiC epitaxial growth layer 13.

In addition, the SiC epitaxial growth layer 13 may have any crystal structure of 4H—SiC, 6H—SiC, or 2H—SiC.

As the n-type doping impurity, for example, N (nitrogen), P (phosphorus), As (arsenic), etc. can be used.

As the p-type doping impurity, for example, B (boron), Al (aluminum), etc. can be used.

The back surface ((000-1) C plane) of the SiC polycrystalline growth layer 17 is provided with a cathode electrode 21 covering the entire area thereof, and the cathode electrode 21 is connected to a cathode terminal K.

In addition, the front surface 13b (for example, the (0001) Si plane) of the SiC epitaxial growth layer 13 is provided with a contact hole 23 that exposes a portion of the SiC epitaxial growth layer 13 as an active region 22, and a field insulating film 25 is formed in a field region 24 surrounding the active region 22.

The field insulating film 25 contains SiO₂ (silicon dioxide), but may also contain other insulators such as silicon nitride (SiN). An anode electrode 26 is formed on the field insulating film 25 and is connected to an anode terminal A.

A p-type Junction Termination Extension (JTE) structure 27 is formed in contact with the anode electrode 26 near the front surface 13b (surface layer portion) of the SiC epitaxial growth layer 13. The JTE structure 27 is formed along the contour of the contact hole 23 so as to span the inside and outside of the contact hole 23 of the field insulating film 25.

### (SiC-TMOSET)

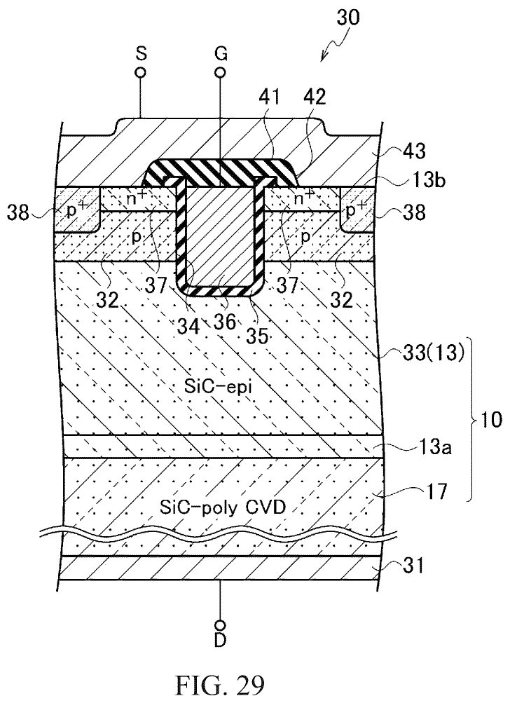

As a semiconductor element produced using the SiC composite substrate 10 of the embodiment, a trench gate TMOSFET 30 has the SiC composite substrate 10 including the SiC polycrystalline growth layer 17 and the SiC epitaxial growth layer 13, as shown in FIG. 29. In addition, the highly doped layer 13a may be interposed between the SiC polycrystalline growth layer 17 and the SiC epitaxial growth layer 13. Here, the highly doped layer 13a can suppress the expansion of the depletion layer that expands in the SiC epitaxial growth layer 13 and easily forms ohmic contact with the SiC polycrystalline growth layer 17 formed on the C plane of the SiC epitaxial growth layer 13. The SiC epitaxial growth layer 13 is a drift layer, the highly doped layer 13a is a buffer layer, and the SiC polycrystalline growth layer 17 is a matrix layer.

The SiC polycrystalline growth layer 17 is doped to n+ type (the impurity density is, for example, between about 1×10¹⁸ cm⁻³ and about 1×10²¹ cm⁻³), and the SiC epitaxial growth layer 13 is doped to n-type (the impurity density is, for example, between about 5×10¹⁴ cm⁻³ and about 5×10¹⁶ cm⁻³). The highly doped layer 13a is doped to a concentration higher than that of the SiC epitaxial growth layer 13.

In addition, the SiC epitaxial growth layer 13 may have any crystal structure of 4H—SiC, 6H—SiC, or 2H—SiC.

As the n-type doping impurity, for example, N (nitrogen), P (phosphorus), As (arsenic), etc. can be used.

As the p-type doping impurity, for example, B (boron), Al (aluminum), etc. can be used.

The back surface ((000-1) C plane) of the SiC polycrystalline growth layer 17 is provided with a drain electrode 31 covering the entire area thereof, and the drain electrode 31 is connected to a drain terminal D.

A p-type (the impurity density is, for example, between about 1×10¹⁶ cm⁻³ and about 1×10¹⁹ cm⁻³) main body region 32 is formed near the front surface 13b ((0001) Si plane) of the SiC epitaxial growth layer 13 (the surface layer portion). In the SiC epitaxial growth layer 13, the portion on the SiC polycrystalline growth layer 17 side with respect to the main body region 32 is an n-type drain region 33 (13) that maintains the state of the SiC epitaxial growth layer 13.

A gate trench 34 is formed in the SiC epitaxial growth layer 13. The gate trench 34 penetrates the main body region 32 from the surface 13b of the SiC epitaxial growth layer 13, and its deepest portion reaches the drain region 33 (13).

A gate insulating film 35 is formed on the inner surface of gate trench 34 and surface 13b of the SiC epitaxial growth layer 13 so as to cover the entire inner surface of the gate trench 34. Also, a gate electrode 36 is buried in the gate trench 34 by filling the inside of the gate insulating film 35 with, for example, polysilicon. The gate electrode 36 is connected to a gate terminal G.

An n⁺-type source region 37 forming a part of the side surface of the gate trench 34 is formed on the surface layer portion of the main body region 32.

In addition, a p⁺-type (the impurity density is, for example, between about 1×10¹⁸ cm⁻³ and about 1×10²¹ cm⁻³) body contact area 38 connected to the main body region 32 is formed in the SiC epitaxial growth layer 13 from its surface 13b to penetrate the source region 37.

An interlayer insulating film 41 containing SiO₂ is formed on the SiC epitaxial growth layer 13. A source electrode 43 is connected to a source region 37 and a body contact region 38 via the contact hole 42 formed in the interlayer insulating film 41. The source electrode 43 is connected to a source terminal S.

In a state where a predetermined potential difference is generated between the source electrode 43 and the drain electrode 31 (between the source and the drain), a predetermined voltage (a voltage equal to or higher than the gate threshold voltage) is applied to the gate electrode 36 so that a channel can be formed in the main body region 32 near the interface with the gate insulating film 35 by the electric field from the gate electrode 36. Thereby, a current can flow between the source electrode 43 and the drain electrode 31, and the SiC-TMOSPET 30 can be brought into an on state.

### (SiC Planar Gate MOSFET)

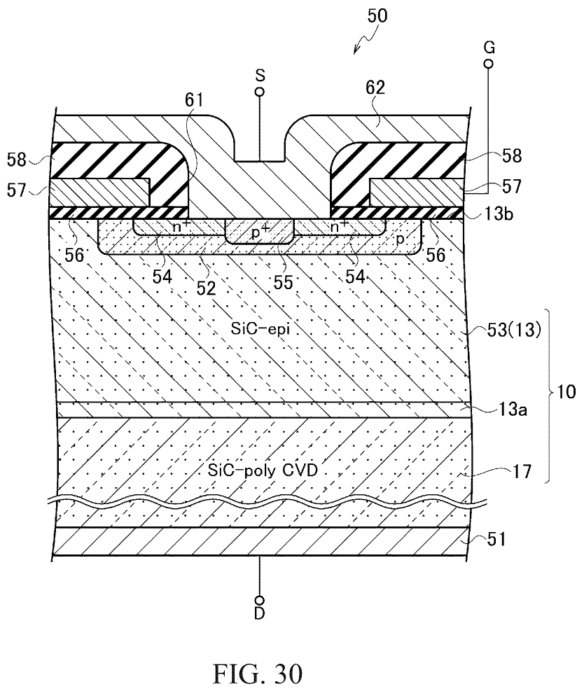

As a semiconductor element produced using the SiC composite substrate 10, a planar gate type MOSFET 50 has the SiC composite substrate 10 including the SiC polycrystalline growth layer 17 and the SiC epitaxial growth layer 13, as shown in FIG. 30. In addition, the highly doped layer 13a may be interposed between the SiC polycrystalline growth layer 17 and the SiC epitaxial growth layer 13. Here, the highly doped layer 13a can suppress the expansion of the depletion layer that expands in the SiC epitaxial growth layer 13 and easily forms ohmic contact with the SiC polycrystalline growth layer 17 formed on the C plane of the SiC epitaxial growth layer 13. The SiC epitaxial growth layer 13 is a drift layer, the highly doped layer 13a is a buffer layer, and the SiC polycrystalline growth layer 17 is a matrix layer.

The SiC polycrystalline growth layer 17 is doped to n+ type (the impurity density is, for example, between about 1×10¹⁸ cm⁻³ and about 1×10²¹ cm⁻³), and the SiC epitaxial growth layer 13 is doped to n⁻-type (the impurity density is, for example, between about 5×10¹⁴ cm⁻³ and about 5×10¹⁶ cm⁻³).

In addition, the SiC epitaxial growth layer 13 may have any crystal structure of 4H—SiC, 6H—SiC, or 2H—SiC.

As the n-type doping impurity, for example, N (nitrogen), P (phosphorus), As (arsenic), etc. can be used.

As the p-type doping impurity, for example, B (boron), Al (aluminum), etc. can be used.

The back surface ((000-1) C plane) of the SiC composite substrate 10 is provided with a drain electrode 51 covering the entire area thereof, and the drain electrode 51 is connected to a drain terminal D.

In the vicinity (surface layer portion) of the front surface 13b ((0001) Si plane) of the SiC epitaxial growth layer 13, a p-type (impurity density, for example, between about 1×10¹⁶ cm⁻³ and about 1×10¹⁹ cm⁻³) main body region 52 is formed as well shaped. In the SiC epitaxial growth layer 13, the portion on the SiC composite substrate 10 side with respect to the main body region 52 is the n-type drain region 53 (13) that maintains the state after epitaxial growth.

An n⁺-type source region 54 is formed at the surface layer portion of the main body region 52 at a distance from the periphery of the main body region 52.

Inside the source region 54, a p⁺-type (impurity density, for example, between about 1×10¹⁸ cm⁻³ and about 1×10²¹ cm⁻³) body contact region 55 is formed. The body contact region 55 penetrates the source region 54 in the depth direction and is connected to the main body region 52.

A gate insulating film 56 is formed on the surface 13b of the SiC epitaxial growth layer 13. The gate insulating film 56 covers the portion of the main body region 52 surrounding the source region 54 (the peripheral portion of the main body region 52) and the outer periphery of the source region 54.

A gate electrode 57 made of, for example, polysilicon is formed on the gate insulating film 56. The gate electrode 57 faces the peripheral portion of the main body region 52 via the gate insulating film 56. The gate electrode 57 is connected to a gate terminal G.

An interlayer insulating film 58 containing SiO₂ is formed on the SiC epitaxial growth layer 13. The source electrode 62 is connected to the source region 54 and the body contact region 55 via the contact hole 61 formed in the interlayer insulating film 58. A source terminal S is connected to the source electrode 62.

In a state where a predetermined potential difference is generated between the source electrode 62 and the drain electrode 51 (between the source and the drain), a predetermined voltage (a voltage equal to or higher than the gate threshold voltage) is applied to the gate electrode 57 so that a channel can be formed in the main body region 52 near the interface with the gate insulating film 56 by the electric field from the gate electrode 57. Thereby, a current can flow between the source electrode 62 and the drain electrode 51, and the planar gate type MOSFET 50 can be brought into an on state.

As described above, according to the embodiment, in the step of surface thermal etching A (see FIG. 7), silicon fluoride gas that selectively performs surface thermal etching on silicon (Si) is introduced into the atmosphere. As a result, Si is etched from the SiC surface, forming an amorphous carbon layer that becomes a graphene precursor. Subsequently, by raising the temperature to 1600° C. or above in the surface thermal decomposition process B (referring to FIG. 7), the carbon concentration on the surface is further increased by selective sublimation of Si, and with the preformed amorphous carbon layer, enough carbon is supplied when graphene is crystallized, such that a graphene layer 12 with low defects can be formed. In addition, silicon fluoride gas may be introduced into the atmosphere in the step of surface thermal decomposition B.

In this way, according to the embodiment, the graphene layer 12 with low defects can be formed. Therefore, when the SiC epitaxial growth layer 13 is formed by the van der Waals epitaxial growth method in the next step, it is possible to improve the resistance of the residual air components and Si precursor decomposition products existing in the furnace chamber 211 to graphene etching.

Instead of performing the procedure of surface thermal etching A, the procedure of surface thermal decomposition B may be performed from the beginning, and the silicon fluoride gas may be used to form graphene in the procedure of surface thermal decomposition B (referring FIG. 9). In this case, since the procedure of surface thermal etching A is not required and the procedure of surface thermal decomposition B is sufficient, the man-hours are reduced and the manufacturing cost is also reduced.

In the embodiment, since the inert gas Ar gas is used as the carrier gas when forming the SiC epitaxial growth layer 13 by using the van der Waals epitaxial growth method, parasitic accumulation is occurred on the furnace wall 211 of the reaction furnace 210, or the formation of gas phase nuclei and particles increases. Therefore, there is a concern that the crystal quality of the SiC epitaxial growth layer 13 will decrease. However, in the embodiment, since the silicon fluoride gas used as the material gas of silicon (Si) in the van der Waals epitaxial growth method has the property of strongly reacting with and removing Si, parasitic accumulation and the increase in formation of gas phase nuclei and particles can be strongly suppressed.

In the embodiment, silicon fluoride gas is used as the Si material gas of the SiC epitaxial growth layer 13 using the van der Waals epitaxial growth method, and hydrocarbon gas is used as the C material gas. Among them, silicon fluoride gas hardly reacts with C, but when silicon fluoride gas coexists, there is a reaction path that produces hydrogen fluoride (HF) which reacts weakly with graphene as a secondary reaction of their decomposition products. However, since the fluorine (F, F₂) freed from the decomposition of silicon fluoride gas has strong reactivity with Si, in general, compared with the case where silane (SiH₄) or dichlorosilane (Si₂H₂Cl₂) is used as the material gas of Si, the use of silicon fluoride gas can better suppress the etching of graphene. In addition, as the material gas of C, fluorocarbon gas may be used together with the hydrocarbon gas or instead of the hydrocarbon gas. However, in this case, the etching of graphene can also be suppressed.

According to the embodiment, by separating the SiC monocrystalline substrate 11 and replacing it with a temporary substrate of the highly heat-resistant graphite substrate 19 before forming the SiC polycrystalline growth layer 17 by CVD, it is possible to prevent unnecessary adhesion of polycrystalline SiC to the SiC monocrystalline substrate 11, maximize the reusability of the SiC monocrystalline substrate 11 and enable further cost reduction.

In the embodiment, the stress layer 14 is formed of a carbon-based film (polycrystalline diamond film or diamond-like carbon film). In the modified example, the stress layer 15 is formed of a silicon nitride film, and utilizing internal stress and thermal stress in the film, it is assumed that the SiC epitaxial growth layer 13 can be easily peeled off from the graphene layer 12. Furthermore, thereby, metal contamination which becomes a problem when using a metal stress film can be avoided. The formation of the carbon-based film or the silicon nitride film has the characteristics of good adhesion to the substrate, excellent high heat resistance, and the ability to obtain large stress.

According to the embodiment, by making the graphite substrate 19 larger than the SiC monocrystalline substrate 11, it is possible to use a batch type vertical tubular furnace or other epitaxial growth device to perform single-sided or double-sided epitaxial growth, reasonably increasing the growth rate and achieving high output and low-cost production. In addition, the graphite substrate 19 and the carbonized adhesive layer 16 can be removed at low cost by simply performing combustion in an oxidation furnace or the like.

According to the embodiment, since van der Waals epitaxial growth of SiC is performed with the interposed graphene formed on the SiC monocrystalline substrate, and the SiC polycrystalline growth layer is formed thereon by the direct CVD method, substrate bonding is not required and defects caused by substrate bonding can be eliminated. In addition, since the epitaxial growth layer is formed with graphene interposed therebetween, the separation of the SiC monocrystalline substrate and the epitaxial growth layer becomes easy, and the process steps become simple. In addition, expensive processes such as ion implantation peeling method are not required.

According to the embodiment, after the SiC monocrystalline substrate is removed, each highly heat-resistant handling substrate is placed in a high-temperature LP-CVD apparatus, so that the SiC polycrystalline growth layer is directly grown on the epitaxial growth layer, thereby eliminating the need for the process of transporting an epitaxial growth layer with a film thickness of several μm from the handling substrate to the support substrate and the process of bonding to the support substrate as well as avoiding defects such as wrinkles, crystal transfer, and bubbles caused by film transport and bonding.

According to the embodiment, the graphene layer formed on the SiC monocrystalline substrate 11 is not transfer-printed, but epitaxial growth is performed directly thereon. This can avoid defects such as wrinkles and cracks caused by the transfer printing of graphene.

According to the embodiment, since the SiC monocrystalline substrate 11 is used as the substrate, hexagonal SiC with less deterioration in crystallinity can be obtained. In addition, although the SiC monocrystalline substrate 11 is difficult to remove by grinding or etching and is expensive, the obtained high-performance single crystal, that is, the SiC epitaxial growth layer 13, can be easily separated due to the van der Waals epitaxial growth using the interposed graphene layer 12 without removal by grinding or etching. Since the expensive SiC monocrystalline substrate 11 can be reused after separation, great advantages can be obtained in terms of cost.

Although the embodiments have been described above, they can also be implemented in other ways. For example, although illustration is omitted, a MOS capacitor can be manufactured using the SiC composite substrate 10. In the MOS capacitor, it can improve yield and reliability.

In addition, although illustration is omitted, a bipolar transistor can also be manufactured using the SiC composite substrate 10. In addition, the SiC composite substrate 10 of the embodiment can also be used for manufacturing SiC-pn diodes, SiCIGBTs, SiC complementary MOSFETs, and the like. The SiC composite substrate 10 can also be applied to other types of devices, such as light emitting diodes (LEDs), semiconductor optical amplifiers (SOAs) and the like.

The SiC epitaxial growth layer 13 may include at least one or more selected from the group consisting of Group IV element semiconductors, Group III-V compound semiconductors, and Group II-VI compound semiconductors.

In addition, the SiC composite substrate 10 and the SiC epitaxial growth layer 13 may be made of any material of 4H—SiC, 6H—SiC or 2H—SiC.

In addition, the SiC monocrystalline substrate 11 and the SiC epitaxial growth layer 13 may include at least one material selected from the group consisting of GaN, BN, AlN, Al₂O₃, Ga₂O₃, diamond, carbon, and graphite as a material system other than SiC.

The semiconductor element including the SiC composite substrate 10 may include any of GaN-based, AlN-based, and gallium oxide-based IGBTs, diodes, MOSFETs, and thyristors, in addition to the SiC-based.

The semiconductor device including the SiC composite substrate 10 may also have any structure of a one-in-one module, a two-in-one module, a four-in-one module, a six-in-one module, a seven-in-one module, an eight-in-one module, a twelve-in-one module, or a fourteen-in-one module.

According to the SiC composite substrate 10, as a substrate material, for example, a low-cost SiC polycrystalline growth layer 17 can be used instead of the high-cost SiC monocrystalline substrate 11.

### (Note 1)

A method of manufacturing a semiconductor substrate, comprising: forming a graphene layer 12 on a Si plane of a SiC monocrystalline substrate 11; forming a SiC epitaxial growth layer 13 on the graphene layer 12; forming a stress layer 14 on the SiC epitaxial growth layer 13; attaching a graphite substrate 19 as a temporary substrate onto the stress layer 14; peeling off the graphene layer 12 from the SiC epitaxial growth layer 13; forming a SiC polycrystalline growth layer 17 on a C plane of the SiC epitaxial growth layer 13 from which the graphene layer 12 has been peeled off, and removing the graphite substrate 19. At least one of the forming of the graphene layer 12 and the forming of the SiC epitaxial growth layer 13 is under an atmosphere including fluorine. By subjecting the SiC monocrystalline substrate 11 to thermal surface etching and thermal surface decomposition in the atmosphere containing fluorine, the graphene layer 12 having a high quality can be formed. In addition, since silicon carbide production is less likely to progress in an atmosphere containing fluorine, the SiC epitaxial growth layer 13 having a high quality can be formed.

### (Note 2)

In the method of manufacturing the semiconductor substrate according to Note 1, the forming of the graphene layer 12 on the Si plane of the SiC monocrystalline substrate includes forming the graphene layer 12 by a surface thermal decomposition of the Si plane of the SiC monocrystalline substrate 11 under the atmosphere including a silicon fluoride gas. The high-quality graphene layer 12 can be formed by surface thermal decomposing the Si plane, sublimating the silicon and crystallizing the carbon.

### (Note 3)

In the method of manufacturing the semiconductor substrate according to Note 2, the silicon fluoride gas includes at least one of silicon tetrafluoride, disilicon hexafluoride and trisilicon octafluoride. The silicon fluoride gas has high reactivity with silicon but low reactivity with graphene.

### (Note 4)

In the method of manufacturing the semiconductor substrate according to Note 2 or Note 3, prior to the forming of the graphene layer 12 by the surface thermal decomposition of the Si plane of the SiC monocrystalline substrate, further comprising a surface thermal etching of the Si plane of the SiC monocrystalline substrate 11 under the atmosphere including the silicon fluoride gas. By etching the silicon on the Si plane to produce a carbon-rich surface, the quality of the graphene layer 12 can be improved.

### (Note 5)

In the method of manufacturing the semiconductor substrate according to any one of Notes 1 to 4, upon the forming of the SiC epitaxial growth layer 13, the atmosphere includes a silicon fluoride gas and at least one of a hydrocarbon gas and a fluorocarbon gas, and the SiC epitaxial growth layer 13 is grown under the atmosphere. A material gas is supplied to the SiC epitaxial growth layer 13.

### (Note 6)

In the method of manufacturing the semiconductor substrate according to Note 5, the silicon fluoride gas includes at least one of silicon tetrafluoride, disilicon hexafluoride and trisilicon octafluoride. This can be set according to a uniform heating length of reactors 210 and 220, etc.

### (Note 7)

In the method of manufacturing the semiconductor substrate according to Note 5 or Note 6, the hydrocarbon gas includes at least one of methane, ethane, propane, ethylene and acetylene. Carbon can be supplied to the SiC epitaxial growth layer 13.

### (Note 8)

In the method of manufacturing the semiconductor substrate according to any one of Notes 5 to 7, the fluorocarbon gas includes at least one of tetrafluoromethane, hexafluoroethane, octafluoride propane, fluoroethylene and fluoroacetylene. Carbon can be supplied to the SiC epitaxial growth layer 13.

### (Note 9)

In the method of manufacturing the semiconductor substrate according to any one of Notes 1 to 8, the atmosphere including fluorine further includes an inert gas. The inert gas can be used as a carrier gas.

### (Note 10)

In the method of manufacturing the semiconductor substrate according to Note 9, the inert gas is an argon gas, which is easily available.

### (Note 11)

In the method of manufacturing the semiconductor substrate according to any one of Notes 1 to 10, the forming of the graphene layer 12 includes forming a graphene buffer layer or a single graphene layer 12, which is suitable for van der Waals epitaxial growth.

### (Note 12)

In the method of manufacturing the semiconductor substrate according to any one of Notes 1 to 11, the stress layer 14 includes a carbon film or a silicon nitride film. The stress layer 14 does not include metal, so that metal contamination does not occur.

### (Note 13)

In the method of manufacturing the semiconductor substrate according to Note 12, the carbon film includes a polycrystalline diamond film or a diamond-like carbon film, and is suitable for generating stress.

### (Note 14)

In the method of manufacturing the semiconductor substrate according to any one of Notes 1 to 13, the graphite substrate 19 of the temporary substrate includes graphite. The graphite substrate 19 can be removed by burning.

### (Note 15)

In the method of manufacturing the semiconductor substrate according to Note 14, the graphite substrate 19 of the temporary substrate has an outline size greater than that of the SiC monocrystalline substrate 11. When inserted into a wafer boat groove of a batch-type vertical CVD furnace and aligned, the wafer boat support marks can be positioned outside an effective substrate area.

### (Note 16)

In the method of manufacturing the semiconductor substrate according to Note 14 or Note 15, the graphite substrate 19 of the temporary substrate includes a glassy carbon film formed on a surface. The glassy carbon film has strong adhesion to the carbon adhesive of the adhesive layer 16.

### (Note 17)

In the method of manufacturing the semiconductor substrate according to any one of Notes 14 to 16, the removing of the graphite substrate 19 of the temporary substrate includes removing the graphite substrate 19 by burning in an air atmosphere or the like.

### (Note 18)

In the method of manufacturing the semiconductor substrate according to Note 14, the attaching of the graphite substrate 19, which is the temporary substrate, onto the stress layer 14 includes attaching the stress layer 14 to the graphite substrate 19 via an adhesive layer 16 made of a carbon adhesive. The carbon adhesive has strong adhesive ability, and by carbonizing it, it is possible to maintain its bonding power even at high temperatures.

### (Note 19)

In the method of manufacturing the semiconductor substrate according to Note 18, further comprising burning and removing the adhesive layer 16. For example, the adhesive layer 16 can be burned and removed together with the graphite substrate 19 in an air atmosphere.

### (Note 20)

In the method of manufacturing the semiconductor substrate according to any one of Notes 1 to 19, prior to the removing of the graphite substrate 19 of the temporary substrate, further comprising: grinding and removing the SiC polycrystalline growth layer 17 and the graphite substrate 19 protruded from an outer periphery of a composite including the graphite substrate 19, the stress layer 14 and the SiC epitaxial growth layer 13 during the forming of the SiC polycrystalline growth layer 17, thereby exposing an outer periphery of the graphite substrate 19. By exposing the graphite substrate 19, it becomes possible to burn it.

### (Note 21)

In the method of manufacturing the semiconductor substrate according to any one of Notes 1 to 20, further comprising forming a highly doped layer 13a having an impurity concentration greater than that of the SiC epitaxial growth layer 13 on the C plane of the SiC epitaxial growth layer 13 contacting the SiC polycrystalline growth layer 17. The highly doped layer 13a suppresses spread of the depletion layer in the SiC epitaxial growth layer 13, and also makes it possible to easily form an ohmic contact with the SiC polycrystalline growth layer 7 formed on the C plane of the SiC epitaxial growth layer 13.

### (Note 22)

A semiconductor manufacturing apparatus, comprising reaction furnaces 210, 220, configured for forming the graphene layer 12 on the SiC monocrystalline substrate 11 according to the method of manufacturing the semiconductor substrate according to any one of Notes 2 to 4. The graphene layer 12 can be formed in an atmosphere containing fluorine.

### (Note 23)

A semiconductor manufacturing apparatus, comprising reaction furnaces 210, 220, configured for forming the SiC epitaxial growth layer on the SiC monocrystalline substrate 11 via the graphene layer 12 according to the method of manufacturing the semiconductor substrate according to any one of Notes 5 to 8. The SiC epitaxial growth layer 13 can be formed in an atmosphere containing fluorine.

### (Note 24)

In the semiconductor manufacturing apparatus of Note 22 or 23, a plurality of the SiC monocrystalline substrates 11 are stackedly supported and storable in the reaction furnace 210. The SiC monocrystalline substrates 11 can be processed in a batch manner.

### (Note 25)

In the semiconductor manufacturing apparatus of Note 22 or 23, a plurality of the SiC monocrystalline substrates 11 can be placed on the table 225 of the reaction furnace 220 according to the modified example. The SiC monocrystalline substrates 11 can be processed in a semi-batch manner.

### (Note 26)

A semiconductor substrate, comprising: a SiC monocrystalline substrate 11; a graphene layer 12 disposed on a Si plane of the SiC monocrystalline substrate 11; an SiC epitaxial growth layer 13 disposed above the SiC monocrystalline substrate 11 by the graphene layer 12; and a stress layer 14 disposed on the Si plane of the SiC epitaxial growth layer 13, wherein the SiC epitaxial growth layer 13 includes fluorine. The SiC epitaxial growth layer 13 is formed with high quality in an atmosphere containing fluorine.

### (Note 27)

In the semiconductor substrate of Note 26, the stress layer 14 includes a carbon film or a silicon nitride film. Since the stress layer 14 does not include metal, it does not cause metal contamination.

### (Note 28)

The semiconductor device is a SiC composite substrate formed from the semiconductor substrate of Note 26 or Note 27, in which the SiC polycrystalline growth layer is formed on the Si plane of the SiC epitaxial growth layer, and a semiconductor element structure is formed on the C plane of the SiC epitaxial growth surface of the SiC composite substrate. By using the low-cost, high-quality SiC composite substrate 10, a low-cost, high-quality semiconductor device can be provided.

### (Note 29)

In the semiconductor device of Note 28, the semiconductor element includes at least one of a SiC Schottky barrier diode, a SiC-MOSFET, a SiC bipolar transistor, a SiC diode, a SiC thyristor and a SiC insulated gate bipolar transistor. Various useful SiC-based semiconductor elements can be provided.

### OTHER EMBODIMENTS

As described above, several embodiments have been described, but the descriptions and drawings that form part of the disclosure are illustrative and should not be understood as limiting. Various alternative embodiments, examples, and operational techniques will become apparent to those skilled in the art from this disclosure. Thus, the embodiments include various embodiments not described here.

### INDUSTRIAL APPLICABILITY

This disclosure can be used in various semiconductor module technologies such as IGBT modules, diode modules, and MOS modules (SiC, GaN, AlN, gallium oxide), and can be applied to a wide range of applications, such as power modules for inverter circuits that drive electric motors used as power sources for electric vehicles (including hybrid vehicles), trains, industrial robots, etc., and power modules for inverter circuits that convert power generated by solar cells, wind power generators, and other power generation devices (especially private power generation devices) into commercial power sources.

1. A method of manufacturing a semiconductor substrate, comprising:
forming a graphene layer on a silicon (Si) plane of a silicon carbide (SIC) monocrystalline substrate;
forming a SiC epitaxial growth layer on the graphene layer;
forming a stress layer on the SiC epitaxial growth layer;
attaching a temporary substrate onto the stress layer;
peeling off the graphene layer from the SiC epitaxial growth layer;
forming a SiC polycrystalline growth layer on a carbon (C) plane of the SiC epitaxial growth layer from which the graphene layer has been peeled off; and
removing the temporary substrate, wherein
at least one of the forming of the graphene layer and the forming of the SiC epitaxial growth layer is under an atmosphere including fluorine.

2. The method of claim 1, wherein
the forming of the graphene layer on the Si plane of the SiC monocrystalline substrate includes
forming the graphene layer by a surface thermal decomposition of the Si plane of the SiC monocrystalline substrate under the atmosphere including a silicon fluoride gas.

3. The method of claim 2, wherein the silicon fluoride gas includes at least one of silicon tetrafluoride, disilicon hexafluoride and trisilicon octafluoride.

4. The method of claim 2, prior to the forming of the graphene layer by the surface thermal decomposition of the Si plane of the SiC monocrystalline substrate, further comprising a surface thermal etching of the Si plane of the SiC monocrystalline substrate under the atmosphere including the silicon fluoride gas.

5. The method of claim 1, wherein
upon the forming of the SiC epitaxial growth layer, the atmosphere includes a silicon fluoride gas and at least one of a hydrocarbon gas and a fluorocarbon gas, and
the SiC epitaxial growth layer is grown under the atmosphere.

6. The method of claim 5, wherein the silicon fluoride gas includes at least one of silicon tetrafluoride, disilicon hexafluoride and trisilicon octafluoride.

7. The method of claim 5, wherein the hydrocarbon gas includes at least one of methane, ethane, propane, ethylene and acetylene.

8. The method of claim 5, wherein the fluorocarbon gas includes at least one of tetrafluoromethane, hexafluoroethane, octafluoride propane, fluoroethylene and fluoroacetylene.

9. The method of claim 1, wherein the atmosphere including fluorine further includes an inert gas.

10. The method of claim 9, wherein the inert gas is an argon gas.

11. The method of claim 1, wherein the forming of the graphene layer includes forming a graphene buffer layer or a single graphene layer.

12. The method of claim 1, wherein the stress layer includes a carbon film or a silicon nitride film.

13. The method of claim 12, wherein the carbon film includes a polycrystalline diamond film or a diamond-like carbon film.

14. The method of claim 1, wherein the temporary substrate includes graphite.

15. The method of claim 14, wherein the temporary substrate has an outline size greater than that of the SiC monocrystalline substrate.

16. The method of claim 14, wherein the temporary substrate includes a glassy carbon film formed on a surface.

17. The method of claim 14, wherein the removing of the temporary substrate includes burning the temporary substrate to remove the temporary substrate.

18. The method of claim 14, wherein the attaching of the temporary substrate onto the stress layer includes attaching the stress layer to the temporary substrate by an adhesive layer made of a carbon adhesive.

19. The method of claim 18, further comprising burning the adhesive layer to remove the adhesive layer.

20. The method of claim 1, prior to the removing of the temporary substrate, further comprising: grinding and removing the SiC polycrystalline growth layer and the temporary substrate protruded from an outer periphery of a composite including the temporary substrate, the stress layer and the SiC epitaxial growth layer during the forming of the SiC polycrystalline growth layer, to expose an outer periphery of the temporary substrate.

21. The method of claim 1, further comprising forming a highly doped layer having an impurity concentration greater than that of the SiC epitaxial growth layer on the C plane of the SiC epitaxial growth layer contacting the SiC polycrystalline growth layer.

22. A semiconductor manufacturing apparatus, comprising:
a reaction furnace, configured for forming the graphene layer on the SiC monocrystalline substrate according to the method of claim 2.

23. A semiconductor manufacturing apparatus, comprising:
A reaction furnace, configured for forming the SiC epitaxial growth layer on the SiC monocrystalline substrate by the graphene layer according to the method of claim 5.

24. The semiconductor manufacturing apparatus of claim 22, wherein a plurality of the SiC monocrystalline substrates are stackedly supported and storable in the reaction furnace.

25. The semiconductor manufacturing apparatus of claim 22, wherein a plurality of the SiC monocrystalline substrates are placeable on a table of the reaction furnace.

26. A semiconductor substrate, comprising:
a SiC monocrystalline substrate;
a graphene layer disposed on a Si plane of the SiC monocrystalline substrate;
an SiC epitaxial growth layer disposed above the SiC monocrystalline substrate by the graphene layer; and
a stress layer disposed on the Si plane of the SiC epitaxial growth layer, wherein the SiC epitaxial growth layer includes fluorine.

27. The semiconductor substrate of claim 26, wherein the stress layer includes a carbon film or a silicon nitride film.

28. A semiconductor device, comprising:
a structure of a semiconductor element formed on the C plane of the SiC epitaxial growth layer of a SiC composite substrate formed from the semiconductor substrate according to claim 26, wherein a SiC polycrystalline growth layer is formed on the Si plane of the SiC epitaxial growth layer.

29. The semiconductor device of claim 28, wherein the semiconductor element includes at least one of a SiC Schottky barrier diode, a SiC-MOSFET, a SiC bipolar transistor, a SiC diode, a SiC thyristor and a SiC insulated gate bipolar transistor.
